(19) United States
(12) Patent Application Publication
(10) Pub. No.: US 2024/0237349 A1
(43) Pub. Date: Jul. 11, 2024

(54) THREE-DIMENSIONAL SEMICONDUCTOR MEMORY DEVICE AND METHOD OF FABRICATING THE SAME

(71) Applicant: Samsung Electronics Co., Ltd., Suwon-si (KR)

(72) Inventors: Hyunsu Hwang, Suwon-si (KR); Un-Byoung Kang, Suwon-si (KR); Jumyong Park, Suwon-si (KR); Dongjoon Oh, Suwon-si (KR); Hyunchul Jung, Suwon-si (KR); Sanghoo Cho, Suwon-si (KR)

(21) Appl. No.: 18/464,348

(22) Filed: Sep. 11, 2023

(30) Foreign Application Priority Data
Jan. 11, 2023 (KR) 10-2023-0004221
Feb. 13, 2023 (KR) 10-2023-0018891

(51) Int. Cl. H10B 43/27; G11C 16/04; H01L 23/528; H01L 25/065; H10B 43/10; H10B 43/35; H10B 43/40; H10B 80/00

(52) U.S. Cl. CPC H10B 43/27; G11C 16/0483; H01L 23/5283; H01L 25/0652; H10B 43/10; H10B 43/35; H10B 43/40; H10B 80/00; H01L 2225/06506

(57) ABSTRACT

A three-dimensional semiconductor memory device may include a bottom structure and a top structure thereon. The bottom structure may include a semiconductor substrate including a cell array region and a connection region extending therefrom, and a first stack including first gate electrodes and first interlayer insulating layers alternately stacked on the semiconductor substrate. The top structure may include a second stack including second gate electrodes and second interlayer insulating layers alternately stacked on the first stack. Respective lengths of the first gate electrodes in a second direction may decrease as a distance in a first direction increases, and respective lengths of the second gate electrodes in the second direction may increase as a distance in the first direction increases. The first direction may be perpendicular to a bottom surface of the semiconductor substrate, and the second direction may be parallel to the bottom surface of the semiconductor substrate.

### CROSS-REFERENCE TO RELATED APPLICATIONS

This U.S. non-provisional patent application claims priority under 35 U.S.C. § 119 to Korean Patent Application Nos. 10-2023-0004221 and 10-2023-0018891, filed on Jan. 11, 2023 and Feb. 13, 2023, respectively, in the Korean Intellectual Property Office, the entire contents of which are hereby incorporated by reference.

### BACKGROUND

The present disclosure relates to a three-dimensional semiconductor memory device and a method of fabricating the same, and in particular, to a nonvolatile three-dimensional semiconductor memory device including a vertical channel structure, a method of fabricating the same, and an electronic system including the same.

A semiconductor device capable of storing a large amount of data may be necessary as a part of an electronic system. Higher integration of semiconductor devices may be necessary to satisfy consumer demands for large data storing capacity, superior performance, and inexpensive prices. In the case of two-dimensional or planar semiconductor devices, since their integration is mainly determined by the area occupied by a unit memory cell, integration is greatly influenced by the level of a fine pattern forming technology. However, the process equipment needed to increase pattern fineness can be expensive and sets a practical limitation on increasing integration for two-dimensional or planar semiconductor devices. Thus, three-dimensional semiconductor memory devices including three-dimensionally arranged memory cells have recently been proposed.

### SUMMARY

Aspects of the inventive concept provide a three-dimensional semiconductor memory device with improved electrical and reliability characteristics and a method of reducing process difficulty and cost in a process of fabricating a three-dimensional semiconductor memory device.

Aspects of the inventive concept provide an electronic system including the three-dimensional semiconductor memory device.

According to some embodiments of the inventive concept, a three-dimensional semiconductor memory device may include a bottom structure and a top structure on the bottom structure. The bottom structure may include a semiconductor substrate that includes a cell array region and a connection region extending from the cell array region, and a first stack that includes first gate electrodes and first interlayer insulating layers alternately stacked on the semiconductor substrate. The top structure may include a second stack that includes second gate electrodes and second interlayer insulating layers alternately stacked on the first stack. Respective lengths of the first gate electrodes in a second direction may decrease as a distance in a first direction from a bottom surface of the semiconductor substrate increases. Respective lengths of the second gate electrodes in the second direction may increase as a distance in the first direction from the bottom surface of the semiconductor substrate increases. The first direction may be perpendicular to the bottom surface of the semiconductor substrate, and the second direction may be parallel to the bottom surface of the semiconductor substrate.

According to some embodiments of the inventive concept, a three-dimensional semiconductor memory device may include a bottom structure and a top structure on the bottom structure. The bottom structure may include a peripheral circuit structure on a semiconductor substrate, and a first cell array structure on the peripheral circuit structure. The top structure may include a second cell array structure, and an interconnection layer on the second cell array structure. The first cell array structure may include a semiconductor layer, a first stack that includes first gate electrodes and first interlayer insulating layers alternately stacked on the semiconductor layer, a cell contact plug electrically connected to one of the first gate electrodes, a source contact plug that is laterally spaced apart from the stack and is electrically connected to the semiconductor layer, and a peripheral penetration plug that is laterally spaced apart from the semiconductor layer and is electrically connected to the peripheral circuit structure. The second cell array structure may include a second stack that includes second gate electrodes and second interlayer insulating layers alternately stacked on the first cell array structure, a first penetration electrode that is laterally spaced apart from the second stack and is electrically connected to the cell contact plug, a second penetration electrode that is laterally spaced apart from the second stack and the first penetration electrode and is electrically connected to the source contact plug, and a third penetration electrode that is laterally spaced apart from the second stack, the first penetration electrode, and the second penetration electrode and is electrically connected to the peripheral penetration plug. The first penetration electrode, the second penetration electrode, and the third penetration electrode may be electrically connected to the interconnection layer.

According to some embodiments of the inventive concept, a method of fabricating a three-dimensional semiconductor memory device may include forming a bottom structure on a first carrier substrate, forming a top structure on a second carrier substrate distinct from the first carrier substrate, inverting the second carrier substrate and the top structure and placing them on the bottom structure, bonding the top structure to the bottom structure, and removing the first carrier substrate and the second carrier substrate. The forming of the bottom structure may include forming a peripheral circuit structure on the first carrier substrate, and forming a first cell array structure on the peripheral circuit structure. The forming of the top structure may include forming an interconnection layer on the second carrier substrate, and forming a second cell array structure on the interconnection layer. The forming of the second cell array structure may include forming a redistribution layer.

### BRIEF DESCRIPTION OF THE DRAWINGS

FIG. 1 is a diagram schematically illustrating an electronic system including a three-dimensional semiconductor memory device, according to some embodiments of the inventive concept.

FIG. 2 is a perspective view schematically illustrating an electronic system including a three-dimensional semiconductor memory device, according to some embodiments of the inventive concept.

FIGS. 3 and 4 are sectional views, which are respectively taken along lines I-I′ and II-II′ of FIG. 2 to illustrate a semiconductor package including a three-dimensional semiconductor memory device, according to some embodiments of the inventive concept.

FIG. 5 is a plan view illustrating a three-dimensional semiconductor memory device according to some embodiments of the inventive concept.

FIGS. 6A and 6B are sectional views, which are respectively taken along lines I-I′ and II-II′ of FIG. 5 to illustrate a three-dimensional semiconductor memory device according to some embodiments of the inventive concept.

FIGS. 7A, 8A, 9A, 10A, 11A, 12A, 13A, and 14A are sectional views, which are respectively taken along a line I-I′ of FIG. 5 to illustrate a method of fabricating a three-dimensional semiconductor memory device, according to some embodiments of the inventive concept.

FIGS. 7B, 8B, 9B, 10B, 11B, 12B, 13B, and 14B are sectional views, which are respectively taken along a line II-II′ of FIG. 5 to illustrate a method of fabricating a three-dimensional semiconductor memory device, according to some embodiments of the inventive concept.

### DETAILED DESCRIPTION

Example embodiments of the inventive concept will now be described more fully with reference to the accompanying drawings, in which example embodiments are shown.

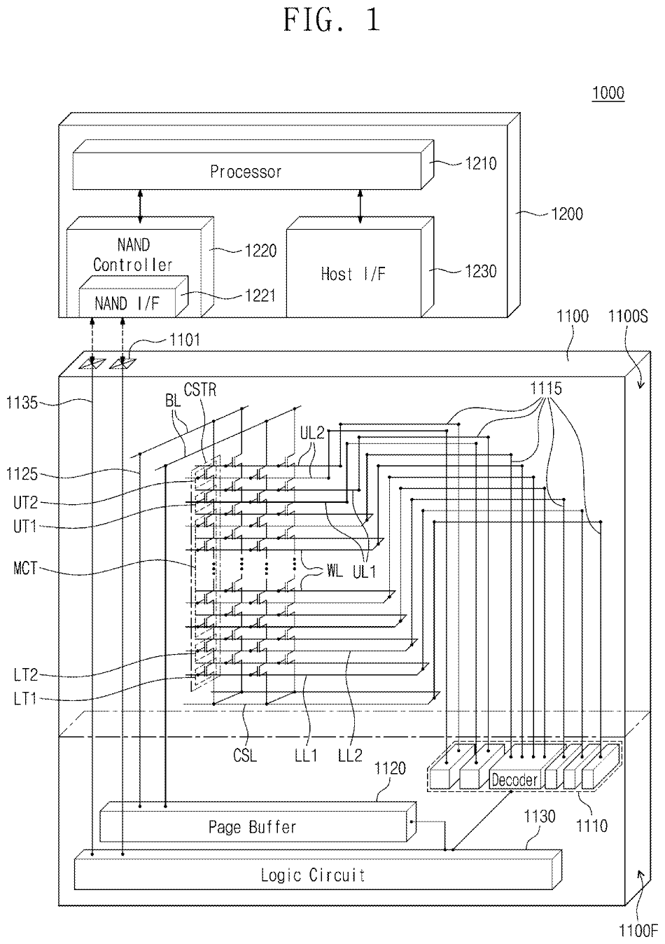

FIG. 1 is a diagram schematically illustrating an electronic system including a three-dimensional semiconductor memory device, according to some embodiments of the inventive concept.

Referring to FIG. 1, an electronic system 1000 may include a three-dimensional semiconductor memory device 1100 and a controller 1200, which is electrically connected to the three-dimensional semiconductor memory device 1100. The electronic system 1000 may be a storage device including one or more three-dimensional semiconductor memory devices 1100 or an electronic device including the storage device. For example, the electronic system 1000 may be a solid state drive (SSD) device, a universal serial bus (USB), a computing system, a medical system, or a communication system, in which at least one three-dimensional semiconductor memory device 1100 is provided.

The three-dimensional semiconductor memory device 1100 may be a nonvolatile memory device (e.g., a three-dimensional NAND FLASH memory device to be described below). The three-dimensional semiconductor memory device 1100 may include a first region 1100F and a second region 1100S on the first region 1100F. For example, the first region 1100F may be disposed near the second region 1100S. The first region 1100F may be a peripheral circuit region, which includes a decoder circuit 1110, a page buffer 1120, and a logic circuit 1130. The second region 1100S may be a memory cell region, which includes a bit line BL, a common source line CSL, word lines WL, first lines LL1 and LL2, second lines UL1 and UL2, and memory cell strings CSTR between the bit line BL and the common source line CSL.

In the second region 1100S, each of the memory cell strings CSTR may include first transistors LT1 and LT2 adjacent to the common source line CSL, second transistors UT1 and UT2 adjacent to the bit line BL, and a plurality of memory cell transistors MCT disposed between the first transistors LT1 and LT2 and the second transistors UT1 and UT2. The number of the first transistors LT1 and LT2 and the number of the second transistors UT1 and UT2 may be variously changed, according to embodiments. In some embodiments, the first transistors LT1 and LT2 may include a ground selection transistor, and the second transistors UT1 and UT2 may include a string selection transistor. The first lines LL1 and LL2 may serve as gate electrodes of the first transistors LT1 and LT2, respectively. The word lines WL may serve as gate electrodes of the memory cell transistors MCT. The second lines UL1 and UL2 may serve as gate electrodes of the second transistors UT1 and UT2, respectively. In some embodiments, the first transistors LT1 and LT2 may include a first erase control transistor LT1 and a ground selection transistor LT2, which are connected in series. The second transistors UT1 and UT2 may include a string selection transistor UT1 and a second erase control transistor UT2, which are connected in series. At least one of the first and second erase control transistors LT1 and UT2 may be used for an erase operation of erasing data, which is stored in the memory cell transistors MCT, using a gate-induced drain leakage (GIDL) phenomenon. The common source line CSL, the first lines LL1 and LL2, the word lines WL, and the second lines UL1 and UL2 may be electrically connected to the decoder circuit 1110 through first interconnection lines 1115, which extend from the first region 1100F to the second region 1100S. The bit line BL may be electrically connected to the page buffer 1120 through second interconnection lines 1125, which extend from the first region 1100F to the second region 1100S.

In the first region 1100F, the decoder circuit 1110 and the page buffer 1120 may be configured to perform a control operation, which is performed on at least a selected one of the memory cell transistors MCT. The decoder circuit 1110 and the page buffer 1120 may be controlled by the logic circuit 1130. The three-dimensional semiconductor memory device 1100 may communicate with the controller 1200 through an input/output pad 1101, which is electrically connected to the logic circuit 1130. The input/output pad 1101 may be electrically connected to the logic circuit 1130 through an input/output interconnection line 1135, which extends from the first region 1100F to the second region 1100S.

The controller 1200 may include a processor 1210, a NAND controller 1220, and a host interface 1230. For example, the electronic system 1000 may include a plurality of three-dimensional semiconductor memory devices 1100, and in this case, the controller 1200 may control the three-dimensional semiconductor memory devices 1100.

The processor 1210 may control overall operations of the electronic system 1000 including the controller 1200. Based on a specific firmware, the processor 1210 may execute operations of controlling the NAND controller 1220 and accessing the three-dimensional semiconductor memory device 1100. The NAND controller 1220 may include a NAND interface 1221, which is used for communication with the three-dimensional semiconductor memory device 1100. The NAND interface 1221 may be used to transmit and receive control commands, which are used to control the three-dimensional semiconductor memory device 1100, data, which will be written in or read from the memory cell transistors MCT of the three-dimensional semiconductor memory device 1100, and so forth. The host interface 1230 may be configured to allow for communication between the electronic system 1000 and an external host. If a control command is received from an external host through the host interface 1230, the processor 1210 may control the three-dimensional semiconductor memory device 1100 in response to the control command.

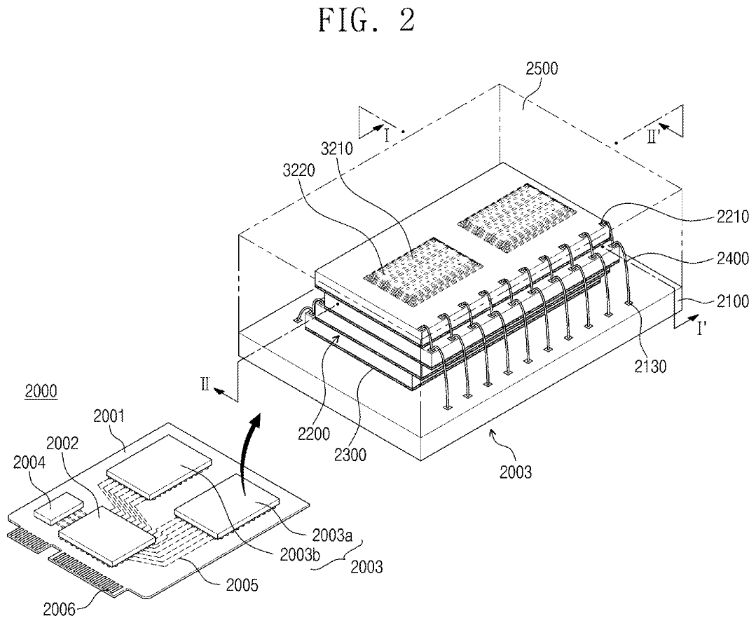

FIG. 2 is a perspective view schematically illustrating an electronic system including a three-dimensional semiconductor memory device, according to some embodiments of the inventive concept.

Referring to FIG. 2, an electronic system 2000 may include a main substrate 2001 and a controller 2002, at least one semiconductor package 2003, and a DRAM 2004, which are mounted on the main substrate 2001. The semiconductor package 2003 and the DRAM 2004 may be connected to the controller 2002 and to each other by interconnection patterns 2005, which are provided in the main substrate 2001. The main substrate 2001 may include a connector 2006, which includes a plurality of pins coupled to an external host. In the connector 2006, the number and arrangement of the pins may depend on a communication interface between the electronic system 2000 and the external host. In some embodiments, the electronic system 2000 may communicate with the external host, in accordance with one of interfaces, such as universal serial bus (USB), peripheral component interconnect express (PCI-Express), serial advanced technology attachment (SATA), universal flash storage (UFS) M-PHY, or the like. In some embodiments, the electronic system 2000 may be driven by an electric power, which is supplied from the external host through the connector 2006. The electronic system 2000 may further include a power management integrated circuit (PMIC), which is used to distribute a power supplied from the external host to the controller 2002 and the semiconductor package 2003.

The controller 2002 may be configured to control a writing or reading operation on the semiconductor package 2003 and to improve an operation speed of the electronic system 2000.

The DRAM 2004 may be a buffer memory, which relieves technical difficulties caused by a difference in speed between the semiconductor package 2003, which serves as a data storage device, and an external host. In some embodiments, the DRAM 2004 in the electronic system 2000 may serve as a cache memory and may provide a storage space, where data is temporarily stored, during various control operations performed on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 respectively disposed on bottom surfaces of the semiconductor chips 2200, a connection structure 2400 electrically connecting the semiconductor chips 2200 to the package substrate 2100, and a molding layer 2500 disposed on the package substrate 2100 to cover the semiconductor chips 2200 and the connection structure 2400.

The package substrate 2100 may be a printed circuit board including package upper pads 2130. Each of the semiconductor chips 2200 may include input/output pads 2210. Each of the input/output pads 2210 may correspond to the input/output pad 1101 of FIG. 1. Each of the semiconductor chips 2200 may include gate stacks 3210 and vertical channel structures 3220. Each of the semiconductor chips 2200 may include a three-dimensional semiconductor memory device, which will be described below.

In some embodiments, the connection structure 2400 may be a bonding wire electrically connecting the input/output pads 2210 to the package upper pads 2130. In each of the first and second semiconductor packages 2003a and 2003b, the semiconductor chips 2200 may be electrically connected to each other in a bonding wire manner and may be electrically connected to the package upper pads 2130 of the package substrate 2100. In some embodiments, the semiconductor chips 2200 in each of the first and second semiconductor packages 2003a and 2003b may be electrically connected to each other by through silicon vias (TSVs), and not by the connection structure 2400 provided in the form of bonding wires.

In some embodiments, the controller 2002 and the semiconductor chips 2200 may be included in a single package. For example, the controller 2002 and the semiconductor chips 2200 may be mounted on an interposer substrate, which is prepared independent of the main substrate 2001, and may be connected to each other through interconnection lines, which are provided in the interposer substrate.

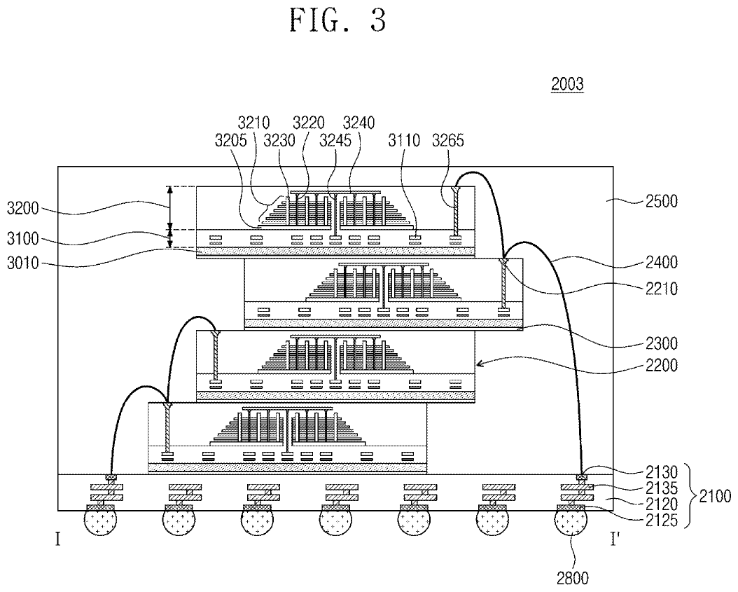

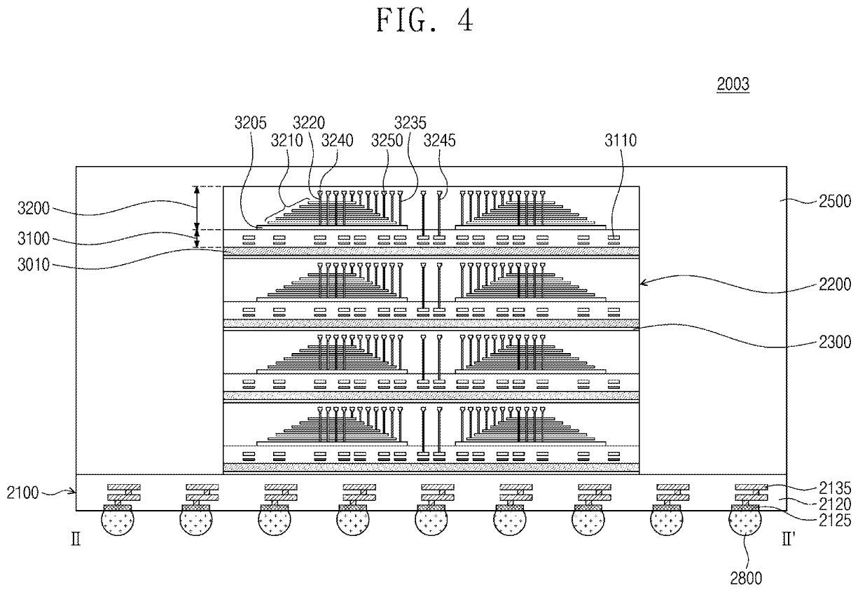

FIGS. 3 and 4 are sectional views, which are respectively taken along lines I-I′ and II-II′ of FIG. 2 to illustrate a semiconductor package including a three-dimensional semiconductor memory device, according to some embodiments of the inventive concept.

Referring to FIGS. 3 and 4, the semiconductor package 2003 may include the package substrate 2100, a plurality of semiconductor chips 2200 on the package substrate 2100, and the molding layer 2500 covering the package substrate 2100 and the semiconductor chips 2200.

The package substrate 2100 may include a package substrate body portion 2120, the package upper pads 2130, which are disposed on or exposed through a top surface of the package substrate body portion 2120, lower pads 2125 disposed on or exposed through a bottom surface of the package substrate body portion 2120, and internal lines 2135 provided in the package substrate body portion 2120 to electrically connect the upper pads 2130 to the lower pads 2125. The package upper pads 2130 may be electrically connected to the connection structures 2400. The lower pads 2125 may be connected to the interconnection patterns 2005 of the main substrate 2001 of the electronic system 2000 shown in FIG. 2 through conductive connecting portions 2800.

Each of the semiconductor chips 2200 may include a semiconductor substrate 3010 and a first structure 3100 and a second structure 3200, which are sequentially stacked on the semiconductor substrate 3010. The first structure 3100 may include a peripheral circuit region, in which peripheral lines 3110 are provided. The second structure 3200 may include a common source line 3205, the gate stack 3210 on the common source line 3205, the vertical channel structures 3220 and separation structures 3230 penetrating or extending in the gate stack 3210, bit lines 3240 electrically connected to the vertical channel structures 3220, gate connection lines 3235 electrically connected to the word lines WL (e.g., see FIG. 1) of the gate stack 3210, and conductive lines 3250.

Each of the semiconductor chips 2200 may be electrically connected to the peripheral lines 3110 of the first structure 3100 and may include a penetration line 3245, which extends into the second structure 3200. The penetration line 3245 may be provided to penetrate or extend in the gate stack 3210 and may be disposed outside the gate stack 3210. Each of the semiconductor chips 2200 may be electrically connected to the peripheral lines 3110 of the first structure 3100 and may further include an input/output connection line 3265, which extends into the second structure 3200, and the input/output pad 2210, which is electrically connected to the input/output connection line 3265.

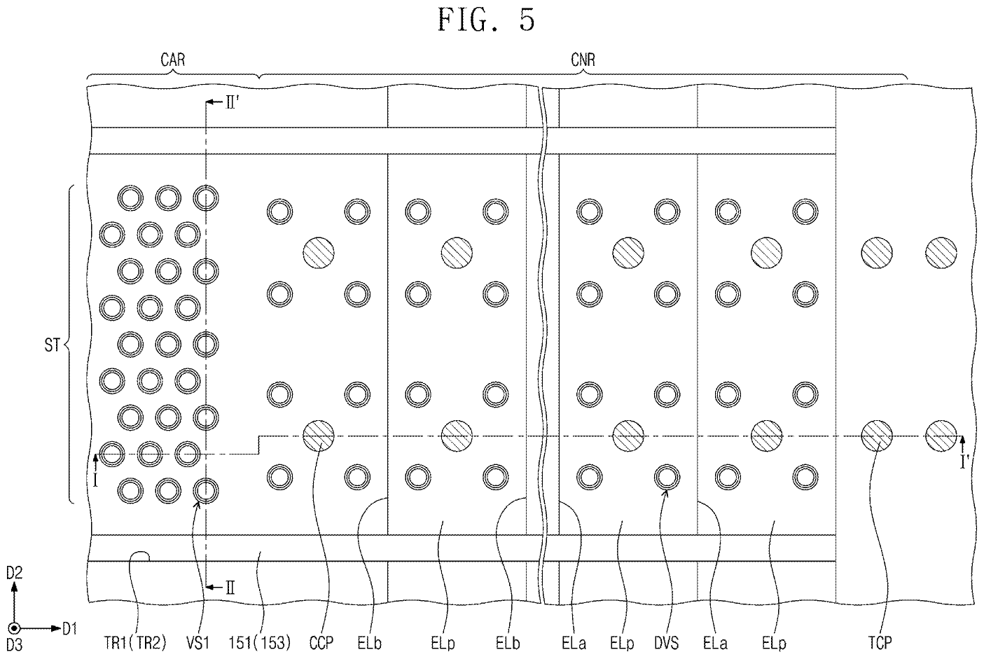

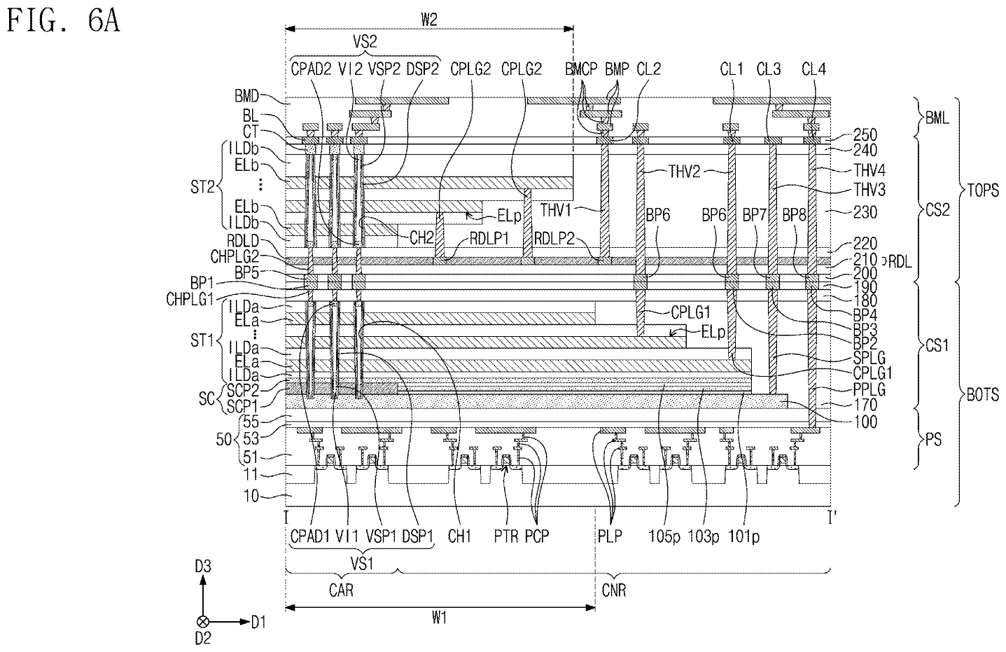

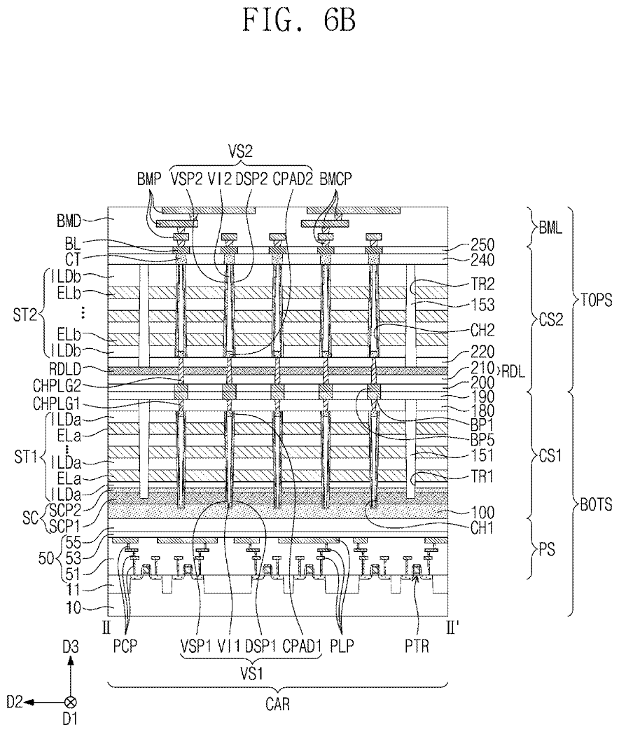

FIG. 5 is a plan view illustrating a three-dimensional semiconductor memory device according to some embodiments of the inventive concept. FIGS. 6A and 6B are sectional views, which are respectively taken along lines I-I′ and II-II′ of FIG. 5 to illustrate a three-dimensional semiconductor memory device according to some embodiments of the inventive concept.

Referring to FIGS. 5, 6A, and 6B, a three-dimensional semiconductor memory device may include a bottom structure BOTS and a top structure TOPS on the bottom structure BOTS.

The bottom structure BOTS may include a peripheral circuit structure PS and a first cell array structure CS1 on the peripheral circuit structure PS.

The peripheral circuit structure PS may include peripheral circuits PTR, which are integrated on a semiconductor substrate 10, and a lower insulating layer 50, which covers the peripheral circuits PTR. In some embodiments, the semiconductor substrate 10 may be a silicon wafer. The semiconductor substrate 10 may include a cell array region CAR and a connection region CNR. A device isolation layer 11 may be provided in the semiconductor substrate 10. The device isolation layer 11 may define an active region of the semiconductor substrate 10. The device isolation layer 11 may be formed of or include silicon oxide.

The peripheral circuits PTR may include row and column decoders, a page buffer, and a control circuit. In detail, the peripheral circuits PTR may include NMOS and PMOS transistors. Peripheral circuit lines PLP may be electrically connected to the peripheral circuits PTR via peripheral contact plugs PCP.

The lower insulating layer 50 may be provided on the semiconductor substrate 10. The lower insulating layer 50 may be provided on the semiconductor substrate 10 to cover the peripheral circuits PTR, the peripheral contact plugs PCP, and the peripheral circuit lines PLP. The peripheral contact plugs PCP and the peripheral circuit lines PLP may be electrically connected to the peripheral circuits PTR.

The lower insulating layer 50 may include a plurality of stacked insulating layers. For example, the lower insulating layer 50 may include a silicon oxide layer, a silicon nitride layer, a silicon oxynitride layer, and/or a low-k dielectric layer. As an example, the lower insulating layer 50 may include a first lower insulating layer 51, a second lower insulating layer 55, and an etch stop layer 53 between the first and second lower insulating layers 51 and 55. The etch stop layer 53 may be formed of or include an insulating material, which is different from the first and second lower insulating layers 51 and 55, and may cover top surfaces of the uppermost peripheral circuit lines PLP.

The first cell array structure CS1 may be disposed on the lower insulating layer 50. The first cell array structure CS1 may include a semiconductor layer 100, a source structure SC, a first stack ST1, first vertical channel structures VS1, dummy vertical structures DVS, first cell contact plugs CPLG1, a source contact plug SPLG, a peripheral penetration plug PPLG, and first to fourth bonding pads BP1, BP2, BP3, and BP4.

The semiconductor layer 100 may be disposed on a top surface of the lower insulating layer 50. The semiconductor layer 100 may be formed of or include at least one of semiconductor, insulating, or conductive materials. The semiconductor layer 100 may be formed of or include a doped semiconductor material of a first conductivity type (e.g., n-type) and/or an undoped or intrinsic semiconductor material. The semiconductor layer 100 may be formed to have one of single-crystalline, poly-crystalline, or amorphous structures.

The source structure SC may be disposed between the semiconductor layer 100 and the first stack ST1. The source structure SC may be parallel to a top surface of the semiconductor layer 100 and may extend parallel to the first stack ST1 in a first direction D1, in the cell array region CAR. A length of the source structure SC in the first direction D1 may be shorter than a length of the semiconductor layer 100 in the first direction D1.

The source structure SC may include a first source conductive pattern SCP1 and a second source conductive pattern SCP2 on the first source conductive pattern SCP1. In the cell array region CAR, the first source conductive pattern SCP1 may be disposed between the semiconductor layer 100 and the first stack ST1. The first source conductive pattern SCP1 may not be provided on the connection region CNR. The first source conductive pattern SCP1 may be formed of or include a semiconductor material that is doped with dopants (e.g., phosphorus (P) or arsenic (As)) to have the first conductivity type. For example, the first source conductive pattern SCP1 may be formed of a poly-silicon layer that is doped with n-type dopants.

In some embodiments, dummy insulating patterns 101p, 103p, and 105p may be disposed between the semiconductor layer 100 and the first stack ST1, in the connection region CNR. The dummy insulating patterns 101p, 103p, and 105p may be located at substantially the same level as the first source conductive pattern SCP1.

The dummy insulating patterns 101p, 103p, and 105p may include a first dummy insulating pattern 101p, a second dummy insulating pattern 103p, and a third dummy insulating pattern 105p, which are sequentially stacked. The second dummy insulating pattern 103p may be formed of or include an insulating material, which is different from the first dummy insulating pattern 101p and the third dummy insulating pattern 105p. The second dummy insulating pattern 103p may be thicker than the first dummy insulating pattern 101p and the third dummy insulating pattern 105p. The first dummy insulating pattern 101p, the second dummy insulating pattern 103p, and the third dummy insulating pattern 105p may be formed of or include at least one of silicon oxide, silicon nitride, silicon oxynitride, silicon carbide, or silicon germanium.

The second source conductive pattern SCP2 may cover a top surface of the first source conductive pattern SCP1 in the cell array region CAR and may cover top surfaces of the dummy insulating patterns 101p, 103p, and 105p in the connection region CNR. The second source conductive pattern SCP2 may be formed of or include a doped semiconductor material of the first conductivity type (e.g., n-type) and/or an undoped or intrinsic semiconductor material.

In the present specification, the first direction D1 may be a direction that is parallel to a bottom surface of the semiconductor substrate 10. A second direction D2 may be a direction that is not parallel to the first direction D1 and is parallel to the bottom surface of the semiconductor substrate 10. A third direction D3 may be a direction that is not parallel to the first and second directions D1 and D2 and is perpendicular to the bottom surface of the semiconductor substrate 10.

The first stack ST1 may be provided on the source structure SC. The first stack ST1 may extend from the cell array region CAR to the connection region CNR. In some embodiments, a plurality of first stacks ST1 may be arranged in the second direction D2 to be spaced apart from each other in the second direction D2, and first separation structures 151 to be described below may be interposed between the first stacks ST1. For ease of description, just one of the first stacks ST1 will be described below, but the others of the first stacks ST1 may also have substantially the same features as described below.

The first stack ST1 may include first interlayer insulating layers ILDa and first gate electrodes ELa, which are alternately stacked on top of one another. For example, the first interlayer insulating layers ILDa and the first gate electrodes ELa may be alternately stacked with each other. The first gate electrodes ELa may correspond to the word lines WL and the first lines LL1 and LL2 of FIG. 1.

Each of the first gate electrodes ELa, as well as each of second gate electrodes ELb to be described below, may have substantially the same thickness in the third direction D3. As used herein, the term ‘thickness’ may be used to denote a length of an element measured in the third direction D3.

Lengths of the first gate electrodes ELa in the first direction D1 may decrease as a distance from the semiconductor layer 100 (i.e., in the third direction D3) increases. That is, the length of each of the first gate electrodes ELa in the first direction D1 may be larger than a length, in the first direction D1, of another one of the first gate electrodes ELa thereon. For example, respective lengths of the first gate electrodes ELa in the first direction D1 may decrease as a distance in the third direction D3 from the bottom surface of the semiconductor substrate 10 increases. When measured in the first direction D1, the lowermost one of the first gate electrodes ELa may have the longest length, and the uppermost one of the first gate electrodes ELa may have the shortest length.

The first gate electrodes ELa may have pad portions ELp on the connection region CNR. The pad portions ELp of the first gate electrodes ELa may be disposed at positions that are horizontally and vertically different from each other. The pad portions ELp may form a stepwise structure in the first direction D1.

Owing to the stepwise structure, the first stack ST1 may have a decreasing thickness with increasing distance from the outermost one of the first vertical channel structures VS1, and when viewed in a plan view, side surfaces of the first gate electrodes ELa may be spaced apart from each other in the first direction D1 by a specific distance.

The first gate electrodes ELa may be formed of or include at least one of, for example, doped semiconductor materials (e.g., doped silicon and so forth), metallic materials (e.g., tungsten, copper, aluminum, and so forth), conductive metal nitrides (e.g., titanium nitride, tantalum nitride, and so forth), or transition metals (e.g., titanium, tantalum, and so forth). In some embodiments, the first gate electrodes ELa may be formed of or include tungsten.

The first interlayer insulating layers ILDa may be provided between the first gate electrodes ELa, and a side surface of each of the first interlayer insulating layers ILDa may be aligned to a side surface of the first gate electrode ELa, which is placed thereunder and is in contact therewith. For example, similar to the first gate electrodes ELa, lengths of the first interlayer insulating layers ILDa in the first direction D1 may decrease as a distance from the semiconductor layer 100 or the bottom surface of the semiconductor substrate 10 increases (e.g., in the third direction D3).

A thickness of each of the first interlayer insulating layers ILDa may be smaller than a thickness of each of the first gate electrodes ELa. In some embodiments, a thickness of the lowermost one of the first interlayer insulating layers ILDa may be smaller than a thickness of each of the others of the first interlayer insulating layers ILDa.

The first interlayer insulating layers ILDa may be formed of or include at least one of, for example, silicon oxide, silicon nitride, silicon oxynitride, and/or low-k dielectric materials. For example, the first interlayer insulating layers ILDa may be formed of or include at least one of high density plasma (HDP) oxide or tetraethylorthosilicate (TEOS).

A first planarization insulating layer 170 may cover the pad portions ELp of the first stack ST1, which are formed to have the stepwise structure. The first planarization insulating layer 170 may have a substantially flat top surface. More specifically, a top surface of the first planarization insulating layer 170 may be substantially coplanar with a top surface of the uppermost one of the first interlayer insulating layers ILDa of the first stack ST1. The first planarization insulating layer 170 may include a single insulating layer or a plurality of stacked insulating layers. The first planarization insulating layer 170 may be formed of or include at least one of, for example, silicon oxide, silicon nitride, silicon oxynitride, and/or low-k dielectric materials. For example, the first planarization insulating layer 170 may be formed of or include an insulating material different from the first interlayer insulating layers ILDa of the first stack ST1. For example, in the case where the first interlayer insulating layers ILDa of the first stack ST1 include high density plasma oxide, the first planarization insulating layer 170 may be formed of or include TEOS.

A first insulating layer 180 and a second insulating layer 190 may be sequentially stacked on the first stack ST1 and the first planarization insulating layer 170. The first insulating layer 180 may cover the top surface of the first planarization insulating layer 170, the top surface of the uppermost one of the first interlayer insulating layers ILDa of the first stack ST1, and the top surfaces of the first vertical channel structures VS1. The second insulating layer 190 may cover a top surface of the first insulating layer 180.

The first insulating layer 180 and the second insulating layer 190 may be formed of or include at least one of, for example, silicon oxide, silicon nitride, silicon oxynitride, and/or low-k dielectric materials. For example, the first insulating layer 180 and the second insulating layer 190 may include an insulating material that is substantially the same as the first planarization insulating layer 170 but is different from the first interlayer insulating layers ILDa of the first stack ST1.

The first vertical channel structures VS1 may be provided on the cell array region CAR to penetrate or extend in the first stack ST1 and the source structure SC. The first vertical channel structures VS1 may be provided to penetrate or extend in at least a portion of the semiconductor layer 100, and a bottom surface of each of the first vertical channel structures VS1 may be located at a level lower than the top surface of the semiconductor layer 100 and the bottom surface of the source structure SC. In other words, the first vertical channel structures VS1 may be in direct contact with the semiconductor layer 100. As used herein, the term ‘level’ may mean a height in the third direction D3 from the bottom surface of the semiconductor substrate 10.

The first vertical channel structures VS1 may be arranged in the first or second direction D1 or D2 to form a zigzag shape, when viewed in the plan view of FIG. 5. The first vertical channel structures VS1 may not be provided on the connection region CNR. The first vertical channel structures VS1 may correspond to the vertical channel structures 3220 of FIGS. 2 to 4. The first vertical channel structures VS1 may correspond to the channel regions of the memory cell transistors MCT and the first transistors LT1 and LT2 of FIG. 1.

The first vertical channel structures VS1 may be provided in first vertical channel holes CH1 penetrating or extending in the first stack ST1. In some embodiments, a width of each of the first vertical channel structures VS1 in the first or second direction D1 or D2 may increase as a height in the third direction D3 increases. For example, in some embodiments, a width of each of the first vertical channel structures VS1 in the first or second direction D1 or D2 may increase as a distance in the third direction D3 from the bottom surface of the semiconductor substrate 10 increases.

The first vertical channel structures VS1 may include a first data storage pattern DSP1 and a first vertical semiconductor pattern VSP1, which are sequentially provided on an inner side surface of each of the first vertical channel holes CH1, a first gapfill insulating pattern VI1, which is provided to fill an internal space enclosed by the first vertical semiconductor pattern VSP1, and a first conductive pad CPAD1, which is provided on the first gapfill insulating pattern VI1. The first conductive pad CPAD1 may be provided in a space, which is enclosed by the first gapfill insulating pattern VI1 and the first data storage pattern DSP1 (or the first vertical semiconductor pattern VSP1). The first conductive pad CPAD1 may be connected to the first vertical semiconductor pattern VSP1. In some embodiments, a top surface of each of the first vertical channel structures VS1 may have a circular, elliptical, or bar shape. The first data storage pattern DSP1 may be provided adjacent to the first stack ST1 to cover side surfaces of the first interlayer insulating layers ILDa and side surfaces of the first gate electrodes ELa. The first vertical semiconductor pattern VSP1 may conformally cover an inner side surface of the first data storage pattern DSP1.

The first vertical semiconductor pattern VSP1 may be provided between the first data storage pattern DSP1 and the first gapfill insulating pattern VI1. The first data storage pattern DSP1 and the first vertical semiconductor pattern VSP1 may be provided in the shape of a pipe or macaroni with a closed bottom. For example, the first data storage pattern DSP1 and the first vertical semiconductor pattern VSP1 may have a closed-end pipe shape.

Although not shown, the first data storage pattern DSP1 may include a first blocking insulating layer, a first charge storing layer, and a first tunneling insulating layer, which are sequentially stacked. The first blocking insulating layer may be disposed adjacent to the first stack ST1 or the source structure SC, and the first tunneling insulating layer may be disposed adjacent to the first vertical semiconductor pattern VSP1. The first charge storing layer may be interposed between the first blocking insulating layer and the first tunneling insulating layer. The first blocking insulating layer may conformally cover an inner side surface of each of the first vertical channel holes CH1. The first charge storing layer may conformally cover an inner side surface of the first blocking insulating layer. The first charge storing layer may be spaced apart from the first interlayer insulating layers ILDa and the first gate electrodes ELa with the first blocking insulating layer interposed therebetween. The first tunneling insulating layer may conformally cover an inner side surface of the first charge storing layer.

The first blocking insulating layer, the first charge storing layer, and the first tunneling insulating layer may extend in the third direction D3. In some embodiments, the Fowler-Nordheim (FN) tunneling phenomenon, which is caused by a voltage difference between the first vertical semiconductor pattern VSP1 and the first gate electrodes ELa, may be used to store or change data in the first data storage pattern DSP1. For example, the first blocking insulating layer and the first tunneling insulating layer may be formed of or include silicon oxide, and the first charge storing layer may be formed of or include silicon nitride or silicon oxynitride.

The first data storage pattern DSP1 may include an opened portion, which is provided in a lower portion thereof. The first vertical semiconductor pattern VSP1 may be exposed to the outside of the first data storage pattern DSP1 through the opened portion. The first source conductive pattern SCP1 of the source structure SC may be in contact with the first vertical semiconductor pattern VSP1. The second source conductive pattern SCP2 of the source structure SC may be spaced apart from the first vertical semiconductor pattern VSP1 with the first data storage pattern DSP1 interposed therebetween. The first source conductive pattern SCP1 may be spaced apart from the first gapfill insulating pattern VI1 with the first vertical semiconductor pattern VSP1 interposed therebetween.

The first vertical semiconductor pattern VSP1 may be formed of or include at least one of doped semiconductor materials or undoped or intrinsic semiconductor materials and may have a poly-crystalline structure. The first conductive pad CPAD1 may be formed of or include at least one of doped semiconductor materials or conductive materials.

First channel plugs CHPLG1 may be provided to penetrate or extend in the first insulating layer 180 and to be connected to the first vertical channel structures VS1. More specifically, the first channel plugs CHPLG1 may be connected to the first conductive pads CPAD1 of the first vertical channel structures VS1, respectively.

The first cell contact plugs CPLG1 may be provided to penetrate or extend in the first insulating layer 180 and the first planarization insulating layer 170 and to be connected to the first gate electrodes ELa. Each of the first cell contact plugs CPLG1 may be provided to penetrate or extend in one of the first interlayer insulating layers ILDa and may be in direct contact with one of the pad portions ELp of the first gate electrodes ELa. The first cell contact plugs CPLG1 may correspond to the gate connection lines 3235 of FIG. 4.

A source contact plug SPLG may be provided to penetrate or extend in the first insulating layer 180 and the first planarization insulating layer 170 and to be connected to the semiconductor layer 100. In some embodiments, a plurality of source contact plugs SPLG may be provided, unlike that illustrated in the drawings.

The peripheral penetration plug PPLG may be provided to penetrate or extend in the first insulating layer 180, the first planarization insulating layer 170, the second lower insulating layer 55, and the etch stop layer 53 and to be electrically connected to the peripheral circuits PTR of the peripheral circuit structure PS. In some embodiments, a plurality of peripheral penetration plugs PPLG may be provided, unlike that illustrated in the drawings. The peripheral penetration plug PPLG may be spaced apart from the semiconductor layer 100, the source structure SC, and the first stack ST1 in the first direction D1. The peripheral penetration plug PPLG may correspond to the penetration line 3245 of FIGS. 3 and 4.

In some embodiments, the first channel plugs CHPLG1, the first cell contact plugs CPLG1, the source contact plug SPLG, and the peripheral penetration plug PPLG may be provided to have an increasing width in the first or second direction D1 or D2, as a height in the third direction D3 increases. For example, in some embodiments, the first channel plugs CHPLG1, the first cell contact plugs CPLG1, the source contact plug SPLG, and the peripheral penetration plug PPLG may have an increasing width in the first or second direction D1 or D2 as a distance in the third direction D3 from the bottom surface of the semiconductor substrate 10 increases. The first channel plugs CHPLG1, the first cell contact plugs CPLG1, the source contact plug SPLG, and the peripheral penetration plug PPLG may be formed of or include at least one of metallic or conductive materials.

The dummy vertical structures DVS may be provided on the connection region CNR. When viewed in a plan view, the dummy vertical structures DVS may be provided around the first cell contact plugs CPLG1. The first cell contact plugs CPLG1 may be spaced apart from each other, and each of them may be adjacent to a plurality of the dummy vertical structures DVS. The dummy vertical structures DVS may not be provided on the cell array region CAR. The dummy vertical structures DVS may have substantially the same structure as the first vertical channel structures VS1. However, in some embodiments, the dummy vertical structures DVS may not be provided.

In some embodiments, a plurality of first stacks ST1 may be provided, and a first separation structure 151 may be provided in a first trench TR1, which is formed between the first stacks ST1 and extends in the first direction D1. The first trench TR1 may extend to a region on the connection region CNR. The first separation structure 151 may be spaced apart from the first vertical channel structures VS1 in the second direction D2. In some embodiments, a top surface of the first separation structure 151 may be located at a level higher than the top surfaces of the first vertical channel structures VS1. A bottom surface of the first separation structure 151 may be located at a level that is lower than a bottom surface of the second source conductive pattern SCP2 and is higher than the top surface of the semiconductor layer 100. The first separation structure 151 may have a single- or multi-layered structure. The first separation structure 151 may be formed of or include at least one of insulating materials (e.g., silicon oxide, silicon nitride, or silicon oxynitride).

In some embodiments, a plurality of first separation structures 151 may be provided, and here, the first separation structures 151 may be spaced apart from each other in the second direction D2, with the first stack ST1 interposed therebetween. The first separation structure 151 may correspond to the separation structures 3230 of FIG. 3.

The first bonding pads BP1 may be provided on the first channel plugs CHPLG1, respectively. The first bonding pads BP1 may be connected to the first channel plugs CHPLG1, respectively. The first bonding pads BP1 may be connected to the first vertical channel structures VS1, respectively, through the first channel plugs CHPLG1.

The second bonding pads BP2 may be provided on the first cell contact plugs CPLG1, respectively. The second bonding pads BP2 may be connected to the first cell contact plugs CPLG1, respectively.

The third bonding pad BP3 may be provided on the source contact plug SPLG. The third bonding pad BP3 may be connected to the source contact plug SPLG.

The fourth bonding pad BP4 may be provided on the peripheral penetration plug PPLG. The fourth bonding pad BP4 may be connected to the peripheral penetration plug PPLG.

The second insulating layer 190 may cover side surfaces of the first bonding pads BP1, side surfaces of the second bonding pads BP2, a side surface of the third bonding pad BP3, and a side surface of the fourth bonding pad BP4. The second insulating layer 190 may not cover top surfaces of the first bonding pads BP1, top surfaces of the second bonding pads BP2, a top surface of the third bonding pad BP3, and a top surface of the fourth bonding pad BP4. The top surfaces of the first bonding pads BP1, the top surfaces of the second bonding pads BP2, the top surface of the third bonding pad BP3, and the top surface of the fourth bonding pad BP4 may be substantially coplanar with a top surface of the second insulating layer 190. The top surfaces of the first bonding pads BP1, the top surfaces of the second bonding pads BP2, the top surface of the third bonding pad BP3, and the top surface of the fourth bonding pad BP4 may be exposed to the outside of the second insulating layer 190.

The top structure TOPS may be provided on the bottom structure BOTS. The top structure TOPS may include a second cell array structure CS2 and a metal line layer BML on the second cell array structure CS2. As used herein, the metal line layer BML may also be referred to as an interconnection layer BML.

The second cell array structure CS2 may include fifth to eighth bonding pads BP5, BP6, BP7, and BP8, a redistribution layer RDL, a second stack ST2, second vertical channel structures VS2, the dummy vertical structures DVS, second cell contact plugs CPLG2, first to fourth penetration electrodes THV1, THV2, THV3, and THV4, bit lines BL, and first to fourth conductive lines CL1, CL2, CL3, and CL4.

The fifth bonding pads BP5 may be provided on the first bonding pads BP1, respectively. The fifth bonding pads BP5 may be in contact with the first bonding pads BP1, respectively. For example, the fifth bonding pads BP5 may be on lower surfaces of the second vertical channel structures VS2, respectively. The fifth bonding pads BP5 may be connected to the first vertical channel structures VS1, respectively, through the first bonding pads BP1. For example, the first and fifth bonding pads BP1 and BP5, which are in contact with each other, may form a single object (e.g., an integrated structure) without any observable interface therebetween. The first and fifth bonding pads BP1 and BP5, which are in contact with each other, may be shown to have side surfaces, which are aligned to each other, but the inventive concept is not limited to this example. For example, when viewed in a plan view, the side surfaces of the first and fifth bonding pads BP1 and BP5, which are in contact with each other, may be spaced apart from each other (e.g., offset from each other).

The sixth bonding pads BP6 may be provided on the second bonding pads BP2, respectively. The sixth bonding pads BP6 may be in contact with the second bonding pads BP2, respectively. The sixth bonding pads BP6 may be connected to the first cell contact plugs CPLG1, respectively, through the second bonding pads BP2. For example, the second and sixth bonding pads BP2 and BP6, which are in contact with each other, may form a single object without any observable interface therebetween. The second and sixth bonding pads BP2 and BP6, which are in contact with each other, may be shown to have side surfaces, which are aligned to each other, but the inventive concept is not limited to this example. When viewed in a plan view, the side surfaces of the second and sixth bonding pads BP2 and BP6, which are in contact with each other, may be spaced apart from each other.

The seventh bonding pad BP7 may be provided on the third bonding pad BP3. Although not shown, a plurality of third bonding pads BP3 and a plurality of seventh bonding pads BP7 may be provided. The seventh bonding pads BP7 may be in contact with the third bonding pads BP3, respectively. The seventh bonding pads BP7 may be connected to the source contact plugs SPLG, respectively, through the third bonding pads BP3. For example, the third and seventh bonding pads BP3 and BP7, which are in contact with each other, may form a single object without any observable interface therebetween. The third and seventh bonding pads BP3 and BP7, which are in contact with each other, may be shown to have side surfaces, which are aligned to each other, but the inventive concept is not limited to this example. When viewed in a plan view, the side surfaces of the third and seventh bonding pads BP3 and BP7, which are in contact with each other, may be spaced apart from each other.

The eighth bonding pad BP8 may be provided on the fourth bonding pad BP4. Although not shown, a plurality of fourth bonding pads BP4 and a plurality of eighth bonding pads BP8 may be provided. The eighth bonding pads BP8 may be in contact with the fourth bonding pads BP4, respectively. The eighth bonding pads BP8 may be connected to the peripheral penetration plugs PPLG, respectively, through the fourth bonding pads BP4. For example, the fourth and eighth bonding pads BP4 and BP8, which are in contact with each other, may form a single object without any observable interface therebetween. The fourth and eighth bonding pads BP4 and BP8, which are in contact with each other, may be shown to have side surfaces, which are aligned to each other, but the inventive concept is not limited to this example. When viewed in a plan view, the side surfaces of the fourth and eighth bonding pads BP4 and BP8, which are in contact with each other, may be spaced apart from each other.

The first to eighth bonding pads BP1, BP2, BP3, BP4, BP5, BP6, BP7, and BP8 may be formed of or include at least one of metallic materials (e.g., copper (Cu), tungsten (W), aluminum (Al), nickel (Ni), or tin (Sn)). In some embodiments, the first to eighth bonding pads BP1, BP2, BP3, BP4, BP5, BP6, BP7, and BP8 may be formed of or include copper (Cu).

A third insulating layer 200 may be provided on the second insulating layer 190. The third insulating layer 200 may cover the top surface of the second insulating layer 190. The third insulating layer 200 may be in contact with the second insulating layer 190. The third insulating layer 200 may cover side surfaces of the fifth bonding pads BP5, side surfaces of the sixth bonding pads BP6, a side surface of the seventh bonding pad BP7, and a side surface of the eighth bonding pad BP8. The third insulating layer 200 may not cover bottom surfaces of the fifth bonding pads BP5, bottom surfaces of the sixth bonding pads BP6, a bottom surface of the seventh bonding pad BP7, and a bottom surface of the eighth bonding pad BP8. The bottom surfaces of the fifth bonding pads BP5, the bottom surfaces of the sixth bonding pads BP6, the bottom surface of the seventh bonding pad BP7, and the bottom surface of the eighth bonding pad BP8 may be substantially coplanar with a bottom surface of the third insulating layer 200. The bottom surfaces of the fifth bonding pads BP5, the bottom surfaces of the sixth bonding pads BP6, the bottom surface of the seventh bonding pad BP7, and the bottom surface of the eighth bonding pad BP8 may be exposed to the outside of the third insulating layer 200. The third insulating layer 200 may be formed of or include at least one of, for example, silicon oxide, silicon nitride, silicon oxynitride, and/or low-k dielectric materials.

A fourth insulating layer 210 may be provided on the third insulating layer 200. The fourth insulating layer 210 may cover a top surface of the third insulating layer 200.

The redistribution layer RDL may be provided on the fourth insulating layer 210. The redistribution layer RDL may include a redistribution insulating layer RDLD, a first redistribution patterns RDLP1, and a second redistribution pattern RDLP2. Although not shown, a plurality of second redistribution patterns RDLP2 may be provided. The redistribution insulating layer RDLD may be provided on the fourth insulating layer 210 to cover a top surface of the fourth insulating layer 210. The redistribution insulating layer RDLD may have a single- or multi-layered structure. The redistribution insulating layer RDLD may be formed of or include at least one of, for example, silicon oxide, silicon nitride, silicon oxynitride, and/or low-k dielectric materials. In some embodiments, the redistribution insulating layer RDLD may be formed of or include at least one of, for example, photosensitive polyimide, polybenzoxazole, phenol-based polymer, or benzocyclobutene-based polymer.

The first redistribution patterns RDLP1 and the second redistribution pattern RDLP2 may be provided in the redistribution insulating layer RDLD. The first redistribution patterns RDLP1 may be connected to the second cell contact plugs CPLG2, respectively, which will be described below. The second redistribution pattern RDLP2 may be connected to the first penetration electrode THV1, which will be described below. The first redistribution patterns RDLP1 and the second redistribution pattern RDLP2 may extend in the second direction D2. Although not shown, the first redistribution patterns RDLP1 may be connected to the second redistribution pattern RDLP2. In some embodiments, the first redistribution patterns RDLP1 and the second redistribution pattern RDLP2 may be used for redistribution of an interconnection path between the second cell contact plug CPLG2 and the first penetration electrode THV1.

When viewed in a vertical section (e.g., see FIG. 6A), the first redistribution patterns RDLP1 and the second redistribution pattern RDLP2 may be disposed at a level different from the fifth to eighth bonding pads BP5, BP6, BP7, and BP8. For example, when viewed in a vertical section, the first redistribution patterns RDLP1 and the second redistribution pattern RDLP2 may be disposed at a level higher than the fifth to eighth bonding pads BP5, BP6, BP7, and BP8. In other words, the first redistribution patterns RDLP1 and the second redistribution pattern RDLP2 may be spaced apart from the fifth to eighth bonding pads BP5, BP6, BP7, and BP8 in the third direction D3.

The first redistribution patterns RDLP1 and the second redistribution pattern RDLP2 may be formed of or include at least one of metallic or conductive materials.

A fifth insulating layer 220 may be provided on the redistribution layer RDL. The fifth insulating layer 220 may cover a top surface of the redistribution insulating layer RDLD. The fifth insulating layer 220 may cover or be on at least a portion of each of top surfaces of the first redistribution patterns RDLP1 and at least a portion of a top surface of the second redistribution pattern RDLP2, but the inventive concept is not limited to this example.

Second channel plugs CHPLG2 may be provided to penetrate or extend in the fourth insulating layer 210, the redistribution insulating layer RDLD, and the fifth insulating layer 220. The second channel plugs CHPLG2 may be connected to the fifth bonding pads BP5, respectively. The second channel plugs CHPLG2 may be connected to the second vertical channel structures VS2, respectively. More specifically, the second channel plugs CHPLG2 may be respectively connected to second conductive pads CPAD2 of the second vertical channel structures VS2, which will be described below.

The second stack ST2 may be provided on the fifth insulating layer 220. The second stack ST2 may extend from the cell array region CAR to the connection region CNR. In some embodiments, a plurality of second stacks ST2 may be arranged in the second direction D2 to be spaced apart from each other in the second direction D2, and second separation structures 153 to be described below may be interposed between the second stacks ST2. For ease of description, just one of the second stacks ST2 will be described below, but the others of the second stacks ST2 may also have substantially the same features as described below.

The second stack ST2 may include second interlayer insulating layers ILDb and the second gate electrodes ELb, which are alternately stacked on top of one another. For example, the second interlayer insulating layers ILDb and the second gate electrodes ELb may be alternately stacked with each other. The second gate electrodes ELb may correspond to the word lines WL and the second lines UL1 and UL2 of FIG. 1.

Lengths of the second gate electrodes ELb in the first direction D1 may increase as a height in the third direction D3 increases. For example, respective lengths of the second gate electrodes ELb in the first direction D1 may increase as a distance in the third direction D3 from the bottom surface of the semiconductor substrate 10 increases. That is, the length of each of the second gate electrodes ELb in the first direction D1 may be smaller than a length, in the first direction D1, of another one of the second gate electrodes ELb thereon. When measured in the first direction D1, the lowermost one of the second gate electrodes ELb may have the shortest length, and the uppermost one of the second gate electrodes ELb may have the longest length.

The uppermost one of the first gate electrodes ELa may have a first width W1. The first width W1 may be a length of the uppermost one of the first gate electrodes ELa in the first direction D1. In other words, the first width W1 may be the shortest length of the first gate electrodes ELa in the first direction D1. The uppermost one of the second gate electrodes ELb may have a second width W2. The second width W2 may be a length of the uppermost one of the second gate electrodes ELb in the first direction D1. In other words, the second width W2 may be the longest length of the second gate electrodes ELb in the first direction D1. The first width W1 may be larger than the second width W2.

The second gate electrodes ELb may include the pad portions ELp, which are provided on the connection region CNR. The pad portions ELp of the second gate electrodes ELb may be disposed at positions that are horizontally and vertically different from each other. The pad portions ELp may form an inverted stepwise structure in the first direction D1.

Owing to the inverted stepwise structure, the second stack ST2 may have a decreasing thickness with increasing distance from the outermost one of the second vertical channel structures VS2, and when viewed in a plan view, side surfaces of the second gate electrodes ELb may be spaced apart from each other in the first direction D1 by a specific distance.

The second gate electrodes ELb may be formed of or include at least one of, for example, doped semiconductor materials (e.g., doped silicon and so forth), metallic materials (e.g., tungsten, copper, aluminum, and so forth), conductive metal nitrides (e.g., titanium nitride, tantalum nitride, and so forth), or transition metals (e.g., titanium, tantalum, and so forth). In some embodiments, the second gate electrodes ELb may be formed of or include tungsten.

The second interlayer insulating layers ILDb may be provided between the second gate electrodes ELb, and a side surface of each of the second interlayer insulating layers ILDb may be aligned to a side surface of the second gate electrode ELb, which is placed thereon and is in contact therewith. That is, similar to the second gate electrodes ELb, lengths of the second interlayer insulating layers ILDb in the first direction D1 may increase as a height in the third direction D3 increases. For example, similar to the second gate electrodes ELb, lengths of the second interlayer insulating layers ILDb in the first direction D1 may increase as a distance from the bottom surface of the semiconductor substrate 10 increases (e.g., in the third direction D3).

A thickness of each of the second interlayer insulating layers ILDb may be smaller than a thickness of each of the second gate electrodes ELb. For example, a thickness of the uppermost one of the second interlayer insulating layers ILDb may be larger than a thickness of each of the others of the first and second interlayer insulating layers ILDa and ILDb.

Except for the lowermost one of the first interlayer insulating layers ILDa and the uppermost one of the second interlayer insulating layers ILDb, all of the first and second interlayer insulating layers ILDa and ILDb may have substantially the same thickness. However, the inventive concept is not limited to this example, and the thicknesses of the first and second interlayer insulating layers ILDa and ILDb may be variously changed, depending on technical properties required for the three-dimensional semiconductor memory device.

The second interlayer insulating layers ILDb may be formed of or include at least one of, for example, silicon oxide, silicon nitride, silicon oxynitride, and/or low-k dielectric materials. For example, the second interlayer insulating layers ILDb may be formed of or include at least one of high density plasma (HDP) oxide or tetraethylorthosilicate (TEOS). The second interlayer insulating layers ILDb may include a material that is the same as or different from the first interlayer insulating layers ILDa.

A second planarization insulating layer 230 may be provided to cover the pad portions ELp of the second stack ST2 having the inverted stepwise structure. The second planarization insulating layer 230 may have substantially flat bottom and top surfaces. More specifically, a bottom surface of the second planarization insulating layer 230 may be substantially coplanar with a bottom surface of the lowermost one of the second interlayer insulating layers ILDb of the second stack ST2. The second planarization insulating layer 230 may include a single insulating layer or a plurality of stacked insulating layers. The second planarization insulating layer 230 may be formed of or include at least one of, for example, silicon oxide, silicon nitride, silicon oxynitride, and/or low-k dielectric materials. For example, the second planarization insulating layer 230 may be formed of or include an insulating material that is different from the second interlayer insulating layers ILDb of the second stack ST2. In the case where the second interlayer insulating layers ILDb of the second stack ST2 are formed of high density plasma oxide, the second planarization insulating layer 230 may be formed of or include TEOS.

A sixth insulating layer 240 and a seventh insulating layer 250 may be sequentially stacked on the second stack ST2 and the second planarization insulating layer 230. The sixth insulating layer 240 may cover a top surface of the second planarization insulating layer 230 and a top surface of the uppermost one of the second interlayer insulating layers ILDb of the second stack ST2. The seventh insulating layer 250 may cover a top surface of the sixth insulating layer 240. The sixth insulating layer 240 and the seventh insulating layer 250 may be formed of or include at least one of, for example, silicon oxide, silicon nitride, silicon oxynitride, and/or low-k dielectric materials. For example, each of the sixth and seventh insulating layers 240 and 250 may be formed of or include an insulating material that is substantially the same as the second planarization insulating layer 230 but is different from the second interlayer insulating layers ILDb of the second stack ST2.

The second vertical channel structures VS2 may be provided on the cell array region CAR to penetrate or extend in the second stack ST2. The second vertical channel structures VS2 may vertically overlap with the first vertical channel structures VS1, respectively. For example, the second vertical channel structures VS2 may overlap with the first vertical channel structures VS1, respectively, in the third direction D3. As used herein, “an element A overlapping with an element B in a direction X” (or similar language) may mean that there is at least one line that extends in the direction X and intersects both the elements A and B. The second vertical channel structures VS2 may be arranged in the first or second direction D1 or D2 to form a zigzag shape, when viewed in the plan view of FIG. 5. The second vertical channel structures VS2 may not be provided on the connection region CNR. The second vertical channel structures VS2 may correspond to the vertical channel structures 3220 of FIGS. 2 to 4. The second vertical channel structures VS2 may correspond to the channel regions of the second transistors UT1 and UT2 and the memory cell transistors MCT of FIG. 1.

The second vertical channel structures VS2 may be provided in second vertical channel holes CH2 penetrating or extending in the second stack ST2. The first and second vertical channel holes CH1 and CH2 may overlap with each other in the third direction D3.

In some embodiments, a width of each of the second vertical channel structures VS2 in the first or second direction D1 or D2 may decrease as a height in the third direction D3 increases. For example, in some embodiments, a width of each of the second vertical channel structures VS2 in the first or second direction D1 or D2 may decrease as a distance in the third direction D3 from the bottom surface of the semiconductor substrate 10 increases.

The second vertical channel structures VS2 may include a second data storage pattern DSP2 and a second vertical semiconductor pattern VSP2, which are sequentially provided on an inner side surface of each of the second vertical channel holes CH2, a second gapfill insulating pattern VI2, which is provided to fill an internal space enclosed by the second vertical semiconductor pattern VSP2, and a second conductive pad CPAD2, which is provided on the second gapfill insulating pattern VI2. The second conductive pad CPAD2 may be provided in a space, which is enclosed by the second gapfill insulating pattern VI2 and the second data storage pattern DSP2 (or the second vertical semiconductor pattern VSP2). The second conductive pad CPAD2 may be connected to the second vertical semiconductor pattern VSP2. A top surface of each of the second vertical channel structures VS2 may have a circular, elliptical, or bar shape. The second data storage pattern DSP2 may be provided adjacent to the second stack ST2 to cover side surfaces of the second interlayer insulating layers ILDb and side surfaces of the second gate electrodes ELb. The second vertical semiconductor pattern VSP2 may conformally cover an inner side surface of the second data storage pattern DSP2.

The second vertical semiconductor pattern VSP2 may be provided between the second data storage pattern DSP2 and the second gapfill insulating pattern VI2. The second data storage pattern DSP2 and the second vertical semiconductor pattern VSP2 may have a pipe or macaroni shape with an opened top. For example, the second data storage pattern DSP2 and the second vertical semiconductor pattern VSP2 may have a closed-end pipe shape.

Although not shown, the second data storage pattern DSP2 may include a second blocking insulating layer, a second charge storing layer, and a second tunneling insulating layer, which are sequentially stacked. The second blocking insulating layer may be disposed adjacent to the second stack ST2, and the second tunneling insulating layer may be disposed adjacent to the second vertical semiconductor pattern VSP2. The second charge storing layer may be interposed between the second blocking insulating layer and the second tunneling insulating layer. The second blocking insulating layer may conformally cover an inner side surface of each of the second vertical channel holes CH2. The second charge storing layer may conformally cover an inner side surface of the second blocking insulating layer. The second charge storing layer may be spaced apart from the second interlayer insulating layers ILDb and the second gate electrodes ELb with the second blocking insulating layer interposed therebetween. The second tunneling insulating layer may conformally cover an inner side surface of the second charge storing layer.

The second blocking insulating layer, the second charge storing layer, and the second tunneling insulating layer may extend in the third direction D3. In some embodiments, the Fowler-Nordheim (FN) tunneling phenomenon, which is caused by a voltage difference between the second vertical semiconductor pattern VSP2 and the second gate electrodes ELb, may be used to store or change data in the second data storage pattern DSP2. For example, the second blocking insulating layer and the second tunneling insulating layer may be formed of or include silicon oxide, and the second charge storing layer may be formed of or include silicon nitride or silicon oxynitride.

The second vertical semiconductor pattern VSP2 may be formed of or include at least one of doped semiconductor materials or undoped or intrinsic semiconductor materials and may have a poly-crystalline structure. The second conductive pad CPAD2 may be formed of or include at least one of doped semiconductor materials or conductive materials.

The first stack ST1, the first vertical channel structures VS1, the second stack ST2, and the second vertical channel structures VS2 may constitute the cell strings CSTR shown in FIG. 1.

Each of the second vertical channel structures VS2 may be connected to a corresponding one of the first vertical channel structures VS1 through the second channel plug CHPLG2, the fifth bonding pad BP5, the first bonding pad BP1, and the first channel plug CHPLG1.

In some embodiments, a plurality of second stacks ST2 may be provided, and a second separation structure 153 may be provided in a second trench TR2, which is formed between the second stacks ST2 and extends in the first direction D1. The second trench TR2 may extend to a region on the connection region CNR. The second separation structure 153 may be spaced apart from the second vertical channel structures VS2 in the second direction D2. The second separation structure 153 may vertically overlap with the first separation structure 151, but the inventive concept is not limited to this example. For example, a top surface of the second separation structure 153 may be located at the same level as top surfaces of the second vertical channel structures VS2. A bottom surface of the second separation structure 153 may be located at the same level as the top surface of the redistribution insulating layer RDLD. The second separation structure 153 may have a single- or multi-layered structure. The second separation structure 153 may be formed of or include at least one of insulating materials (e.g., silicon oxide, silicon nitride, or silicon oxynitride).

In some embodiments, a plurality of second separation structures 153 may be provided, and the second separation structures 153 may be spaced apart from each other in the second direction D2, with the second stack ST2 interposed therebetween. The second separation structure 153 may correspond to the separation structures 3230 of FIG. 3.

On the connection region CNR, the second cell contact plugs CPLG2 may be provided to penetrate or extend in the second planarization insulating layer 230 and the fifth insulating layer 220 and to be connected to the second gate electrodes ELb. Each of the second cell contact plugs CPLG2 may penetrate or extend in one of the second interlayer insulating layers ILDb and may be in direct contact with one of the pad portions ELp of the second gate electrodes ELb. The second cell contact plugs CPLG2 may be connected to the first redistribution patterns RDLP1. The second cell contact plugs CPLG2 may correspond to the gate connection lines 3235 of FIG. 4.

A first penetration electrode THV1 may be provided on the connection region CNR to penetrate or extend in the sixth insulating layer 240, the second planarization insulating layer 230, and the fifth insulating layer 220. The first penetration electrode THV1 may be connected to a second conductive line CL2, which will be described below. Although not shown, in some embodiments, a plurality of first penetration electrodes THV1 may be provided. The first penetration electrode THV1 may be connected to the second redistribution pattern RDLP2. Thus, the second cell contact plugs CPLG2 may be connected to the second conductive lines CL2, respectively, through the first redistribution patterns RDLP1, the second redistribution pattern RDLP2, and the first penetration electrode THV1.

The second penetration electrodes THV2, the third penetration electrode THV3, and the fourth penetration electrode THV4 may be provided on the connection region CNR to penetrate or extend in the sixth insulating layer 240, the second planarization insulating layer 230, the fifth insulating layer 220, the redistribution insulating layer RDLD, and the fourth insulating layer 210. The second penetration electrodes THV2 may be connected to the sixth bonding pads BP6, respectively. The second penetration electrodes THV2 may be connected to the first conductive lines CL1, respectively, which will be described below. The third penetration electrode THV3 may be connected to the seventh bonding pad BP7. The third penetration electrode THV3 may be connected to the third conductive line CL3 to be described below. The fourth penetration electrode THV4 may be connected to the eighth bonding pad BP8. The fourth penetration electrode THV4 may be connected to the fourth conductive line CL4 to be described below.

The second penetration electrodes THV2 may be connected to the first cell contact plugs CPLG1, respectively, through the sixth bonding pads BP6 and the second bonding pads BP2. In other words, the first gate electrodes ELa may be connected to the first conductive lines CL1, respectively, through the first cell contact plugs CPLG1, the second bonding pads BP2, the sixth bonding pads BP6, and the second penetration electrodes THV2.

The third penetration electrode THV3 may be connected to the source contact plug SPLG through the seventh bonding pad BP7 and the third bonding pad BP3. In other words, the semiconductor layer 100 may be connected to the third conductive line CL3 through the source contact plug SPLG, the third bonding pad BP3, the seventh bonding pad BP7, and the third penetration electrode THV3.

The fourth penetration electrode THV4 may be connected to the peripheral penetration plug PPLG through the eighth bonding pad BP8 and the fourth bonding pad BP4. In other words, the peripheral circuit structure PS may be connected to the fourth conductive line CL4 through the peripheral penetration plug PPLG, the fourth bonding pad BP4, the eighth bonding pad BP8, and the fourth penetration electrode THV4.

When viewed in a plan view, the dummy vertical structures DVS may be provided around the second cell contact plugs CPLG2. Each of the second cell contact plugs CPLG2 may be adjacent to the dummy vertical structures DVS, and the second cell contact plugs CPLG2 may be spaced apart from each other. However, in some embodiments, the dummy vertical structures DVS may not be provided.

Upper conductive pads CT may be provided on the second vertical channel structures VS2, respectively. The upper conductive pads CT may cover the top surfaces of the second vertical channel structures VS2, respectively. The upper conductive pads CT may be connected to the second vertical semiconductor pattern VSP2. The upper conductive pads CT may have top surfaces that are substantially coplanar with the top surface of the sixth insulating layer 240. The upper conductive pads CT may be formed of or include at least one of doped semiconductor materials or conductive materials.

The bit lines BL, which are connected to the second channel plugs CHPLG2, may be provided on the upper conductive pads CT. The bit lines BL may correspond to the bit line BL of FIG. 1 and the bit lines 3240 of FIGS. 3 and 4.

The first conductive lines CL1 connected to the second penetration electrodes THV2, the second conductive line CL2 connected to the first penetration electrode THV1, the third conductive line CL3 connected to the third penetration electrode THV3, and the fourth conductive line CL4 connected to the fourth penetration electrode THV4 may be provided on the sixth insulating layer 240. The first to fourth conductive lines CL1, CL2, CL3, and CL4 may correspond to the conductive lines 3250 of FIG. 4.

As described above, the first conductive lines CL1 may be connected to the first cell contact plugs CPLG1, respectively. The second conductive line CL2 may be connected to the second cell contact plug CPLG2. The third conductive line CL3 may be connected to the source contact plug SPLG. The fourth conductive line CL4 may be connected to the peripheral penetration plug PPLG.

The second channel plugs CHPLG2, the second cell contact plugs CPLG2, the first to fourth penetration electrodes THV1, THV2, THV3, and THV4, the bit lines BL, and the first to fourth conductive lines CL1, CL2, CL3, and CL4 may be formed of or include at least one of metallic or conductive materials.

The metal line layer BML may be provided on the bit lines BL and the first to fourth conductive lines CL1, CL2, CL3, and CL4. The metal line layer BML may include an interconnection insulating layer BMD, metal lines BMP, and interconnection contact plugs BMCP.

The interconnection insulating layer BMD may be provided on the seventh insulating layer 250 to cover the metal lines BMP and the interconnection contact plugs BMCP. The interconnection insulating layer BMD may include a plurality of stacked insulating layers. For example, the interconnection insulating layer BMD may include a silicon oxide layer, a silicon nitride layer, a silicon oxynitride layer, and/or a low-k dielectric layer. The metal lines BMP and the interconnection contact plugs BMCP may be electrically connected to the bit lines BL and the first to fourth conductive lines CL1, CL2, CL3, and CL4, respectively. The metal lines BMP and the interconnection contact plugs BMCP may be formed of or include at least one of metallic or conductive materials.

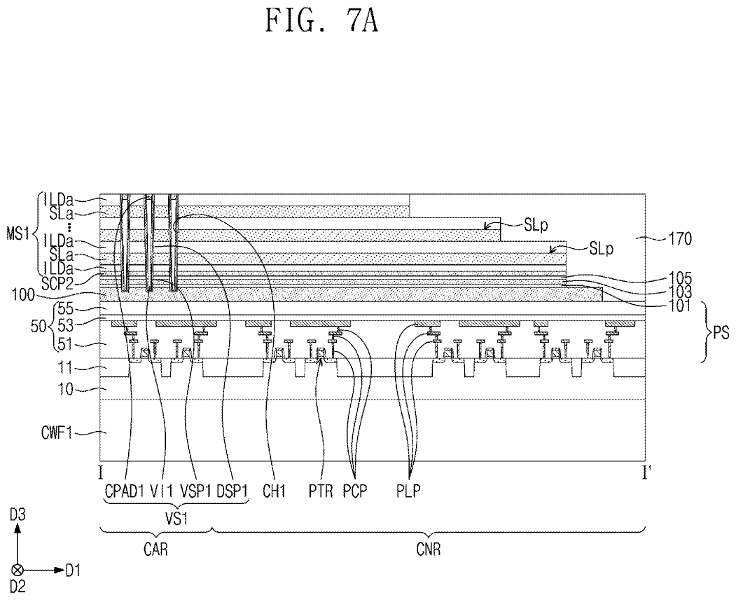

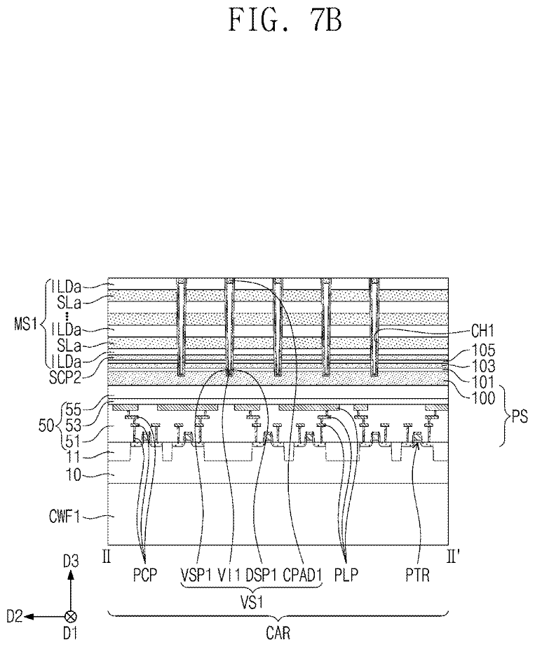

FIGS. 7A, 8A, 9A, 10A, 11A, 12A, 13A, and 14A are sectional views, which are respectively taken along a line I-I′ of FIG. 5 to illustrate a method of fabricating a three-dimensional semiconductor memory device, according to some embodiments of the inventive concept. FIGS. 7B, 8B, 9B, 10B, 11B, 12B, 13B, and 14B are sectional views, which are respectively taken along a line II-II' of FIG. 5 to illustrate a method of fabricating a three-dimensional semiconductor memory device, according to some embodiments of the inventive concept.

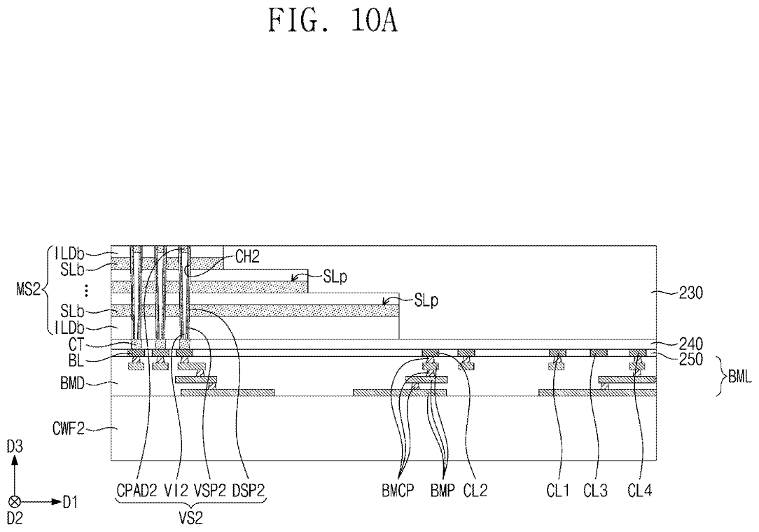

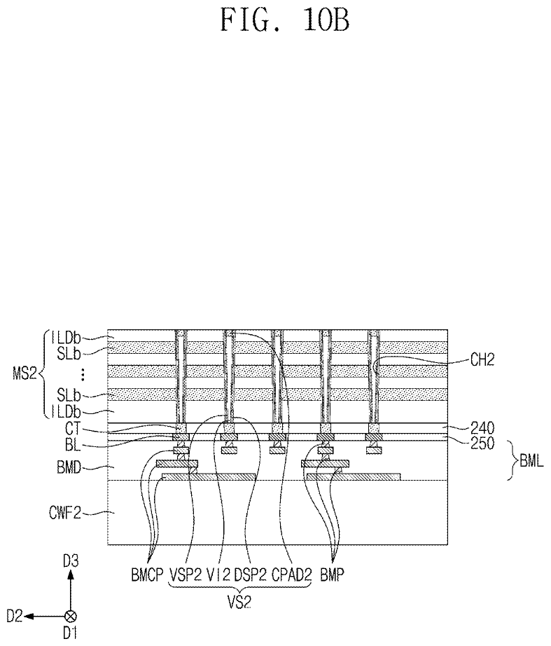

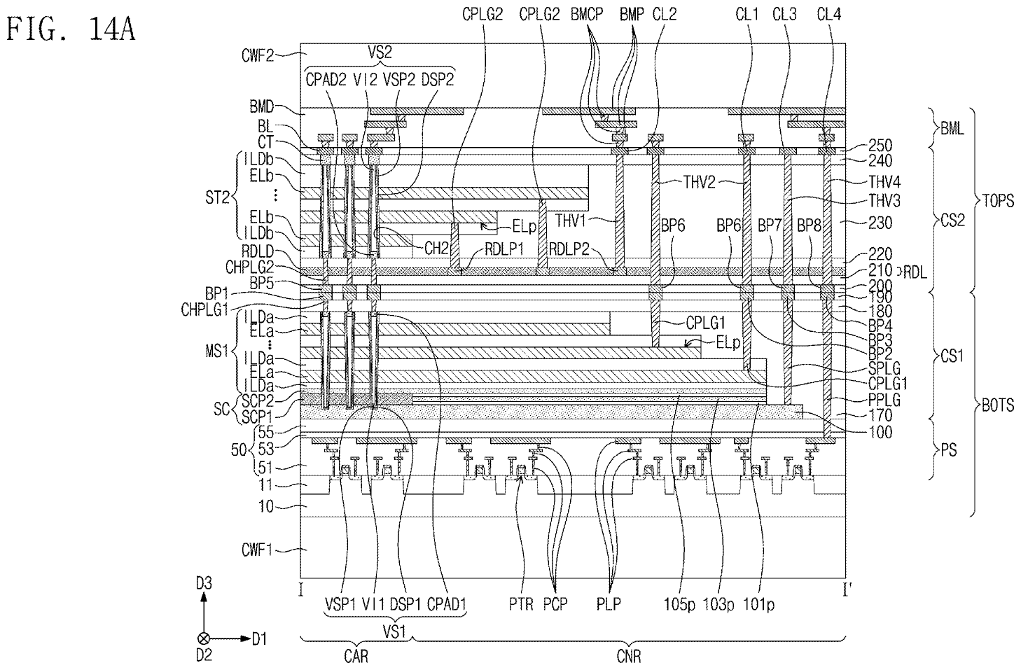

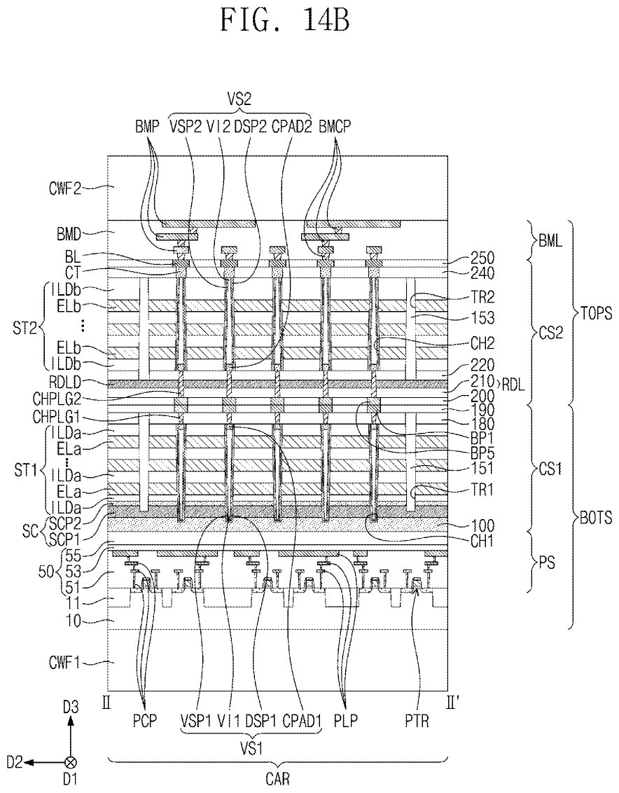

More specifically, FIGS. 7A to 9B illustrate steps of fabricating the bottom structure BOTS, FIGS. 10A to 13B illustrate steps of fabricating the top structure TOPS, and FIGS. 14A and 14B illustrate steps of combining the bottom structure BOTS with the top structure TOPS to fabricate a three-dimensional semiconductor memory device.

Hereinafter, a method of fabricating a three-dimensional semiconductor memory device, according to some embodiments of the inventive concept, will be described in more detail with reference to FIGS. 5 to 14B.

Referring to FIGS. 5, 7A, and 7B, the semiconductor substrate 10 including the cell array region CAR and the connection region CNR may be provided on a first carrier substrate CWF1. The device isolation layer 11 may be formed in the semiconductor substrate 10 to define an active region. The device isolation layer 11 may be formed by forming a trench in an upper portion of the semiconductor substrate 10 and filling the trench with a silicon oxide layer.

The peripheral circuits PTR may be formed on the active region defined by the device isolation layer 11. The peripheral contact plugs PCP and the peripheral circuit lines PLP, which are connected to the peripheral circuits PTR, may be formed. The lower insulating layer 50 may be formed to cover the peripheral circuits PTR, the peripheral contact plugs PCP, and the peripheral circuit lines PLP.

The lower insulating layer 50 may include one or more insulating layers covering the peripheral circuits PTR. The lower insulating layer 50 may include the first lower insulating layer 51, the second lower insulating layer 55, and the etch stop layer 53 between the first and second lower insulating layers 51 and 55. The lower insulating layer 50 may include, for example, a silicon oxide layer, a silicon nitride layer, a silicon oxynitride layer, and/or a low-k dielectric layer.

The semiconductor layer 100 may be formed on the lower insulating layer 50. The semiconductor layer 100 may be formed by depositing a semiconductor material. The semiconductor layer 100 may be formed of or include at least one of silicon (Si), germanium (Ge), silicon germanium (SiGe), gallium arsenic (GaAs), indium gallium arsenic (InGaAs), or aluminum gallium arsenic (AlGaAs). The semiconductor layer 100 may be formed of or include a doped semiconductor material and/or an undoped or intrinsic semiconductor material. The semiconductor layer 100 may be formed to have one of single-crystalline, poly-crystalline, or amorphous structures.

A first insulating pattern 101, a second insulating pattern 103, and a third insulating pattern 105 may be sequentially formed on the semiconductor layer 100. The first insulating pattern 101 may be formed by thermally oxidizing a surface of the semiconductor layer 100 or by depositing a silicon oxide layer. The second insulating pattern 103 may be formed of or include a material having an etch selectivity with respect to the first insulating pattern 101 and the third insulating pattern 105. As an example, the second insulating pattern 103 may be formed of or include at least one of silicon nitride, silicon oxynitride, silicon carbide, or silicon germanium. The third insulating pattern 105 may be formed by depositing a silicon oxide layer.

The second source conductive pattern SCP2 may be deposited on the third insulating pattern 105 to have a uniform thickness. The second source conductive pattern SCP2 may be formed of or include a doped semiconductor material (e.g., of a first conductivity type or an n-type) and/or an undoped or intrinsic semiconductor material.

A first mold structure MS1 may be formed on the second source conductive pattern SCP2. The formation of the first mold structure MS1 may include forming a layered structure (not shown), in which the first interlayer insulating layers ILDa and first sacrificial layers SLa are vertically and alternately stacked and repeatedly performing a patterning process on the layered structure. As a result, the first mold structure MS1 may have a stepwise structure on the connection region CNR. More specifically, the first mold structure MS1 may have preliminary pad portions SLp on the connection region CNR.

In the first mold structure MS1, the first sacrificial layers SLa may be formed of a material which can be etched with a high etch selectivity with respect to the first interlayer insulating layers ILDa. For example, the first sacrificial layers SLa may be formed of an insulating material different from the first interlayer insulating layers ILDa. The first sacrificial layers SLa may be formed of the same material as the second insulating pattern 103. For example, the first sacrificial layers SLa may be formed of or include silicon nitride, and the first interlayer insulating layers ILDa may be formed silicon oxide.

The first planarization insulating layer 170 may be formed to cover the preliminary pad portions SLp of the first mold structure MS1.

Next, the first vertical channel structures VS1 may be formed on the cell array region CAR to penetrate or extend in the first mold structure MS1. The formation of the first vertical channel structures VS1 may include forming the first vertical channel holes CH1 to penetrate or extend in the first mold structure MS1, the second source conductive pattern SCP2, the first insulating pattern 101, the second insulating pattern 103, and the third insulating pattern 105 and sequentially depositing a first data storing layer (not shown) and a first vertical semiconductor layer (not shown) in each of the first vertical channel holes CH1. In the formation of the first vertical channel structures VS1, the first vertical channel holes CH1 may be formed to have bottom surfaces that are located at a level lower than the top surface of the semiconductor layer 100.

The first data storing layer may be conformally deposited on bottom and side surfaces of the first vertical channel holes CH1 by a chemical vapor deposition (CVD) method or an atomic layer deposition (ALD) method. The first data storing layer may include a first tunneling insulating layer, a first charge storing layer, and a first blocking insulating layer, which are sequentially stacked. The first vertical semiconductor layer may be conformally deposited on the first data storing layer by the CVD or ALD method. After the formation of the first data storing layer and the first vertical semiconductor layer, the first vertical channel holes CH1 may be filled with a first insulating gapfill layer (not shown). Next, a planarization process may be performed on the first insulating gapfill layer, the first vertical semiconductor layer, and the first data storing layer to expose a top surface of the uppermost one of the first interlayer insulating layers ILDa of the first mold structure MS1. Thereafter, an etch-back process may be performed on an upper portion of the first insulating gapfill layer, a first conductive pad layer (not shown) may be formed to fill the upper portion of the first insulating gapfill layer, and a planarization process may be performed on the first conductive pad layer to expose the top surface of the uppermost ones of the first interlayer insulating layers ILDa of the first mold structure MS1. As a result, the first data storage patterns DSP1 the first vertical semiconductor patterns VSP1, the first gapfill insulating patterns VI1, and the first conductive pads CPAD1 may be formed, as previously described with reference to FIGS. 6A and 6B.

Although not shown, the dummy vertical structures DVS may be formed. In some embodiments, the dummy vertical structures DVS may be formed by substantially the same method as that for the first vertical channel structures VS1.

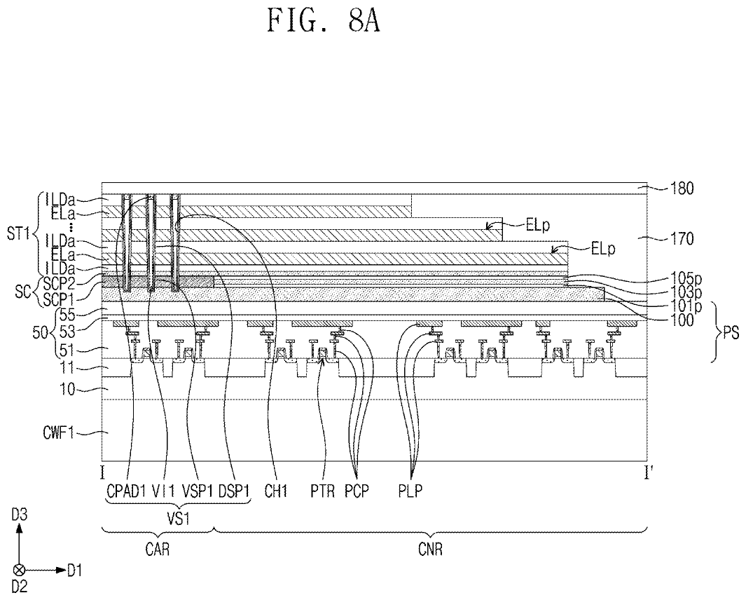

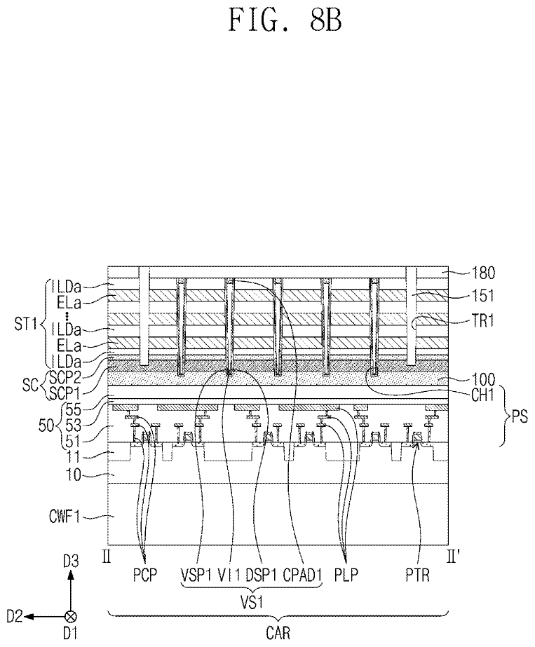

Referring to FIGS. 5, 8A, and 8B, the first insulating layer 180 may be formed on the first planarization insulating layer 170 and the first mold structure MS1 to cover the top surfaces of the first vertical channel structures VS1.

The first trenches TR1 may be formed to penetrate or extend in the first insulating layer 180, the first planarization insulating layer 170, and the first mold structure MS1. The first trenches TR1 may be formed by anisotropically etching the first insulating layer 180, the first planarization insulating layer 170, and the first mold structure MS1. The first trenches TR1 may be formed to further penetrate or extend in the second source conductive pattern SCP2 and the third insulating pattern 105. The first trenches TR1 may further penetrate or extend in at least a portion of the second insulating pattern 103 in the third direction D3. Bottom surfaces of the first trenches TR1 may be, for example, located at a level between a bottom surface of the third insulating pattern 105 and a top surface of the second insulating pattern 103. The first trenches TR1 may expose side surfaces of the first interlayer insulating layers ILDa, side surfaces of the first sacrificial layers SLa, a side surface of the first insulating pattern 101, a side surface of the second insulating pattern 103, and a side surface of the third insulating pattern 105. The first trench TR1 may extend from the cell array region CAR toward the connection region CNR.

After the formation of the first trenches TR1, a replacement process may be performed to replace the first insulating pattern 101, the second insulating pattern 103, and the third insulating pattern 105 in the cell array region CAR with the first source conductive pattern SCP1. Before the forming of the first source conductive pattern SCP1, an insulating layer (not shown) may be formed to cover side surfaces of the first trenches TR1.

The formation of the first source conductive pattern SCP1 may include performing an isotropic etching process on the first insulating pattern 101, the second insulating pattern 103, and the third insulating pattern 105 exposed by the first trenches TR1. During the isotropic etching process, portions of the first data storage patterns DSP1 may also be isotropically etched to expose portions of the first vertical semiconductor patterns VSP1. After the partial exposing of the first vertical semiconductor patterns VSP1, a doped poly-silicon layer may be deposited to form the first source conductive pattern SCP1. As a result, the source structure SC including the first and second source conductive patterns SCP1 and SCP2 may be formed.

After the formation of the first source conductive pattern SCP1, the insulating layer (not shown) covering the side surfaces of the first trenches TR1 may be removed, and then, the first sacrificial layers SLa exposed by the first trench TR1 may be selectively removed. The selective removal of the first sacrificial layers SLa may be performed through a wet etching process using etching solution. The first gate electrodes ELa may be formed to fill spaces, which are formed by the removing of the first sacrificial layers SLa. As a result, the first stack ST1 including the first gate electrodes ELa and the first interlayer insulating layers ILDa may be formed.

The first separation structure 151 may be formed to fill the first trench TR1. The first separation structure 151 may extend from the cell array region CAR toward the connection region CNR. The first separation structure 151 may be formed of or include at least one of insulating materials (e.g., silicon oxide, silicon nitride, or silicon oxynitride).

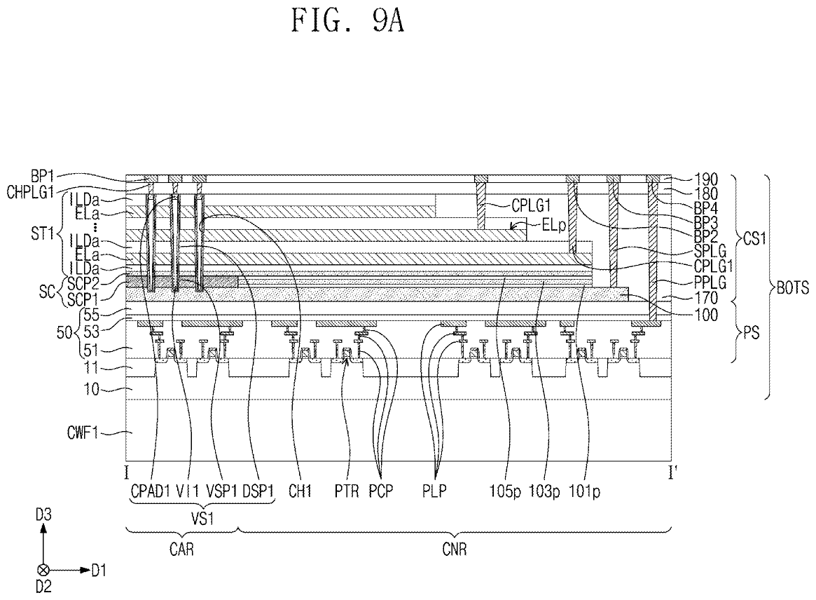

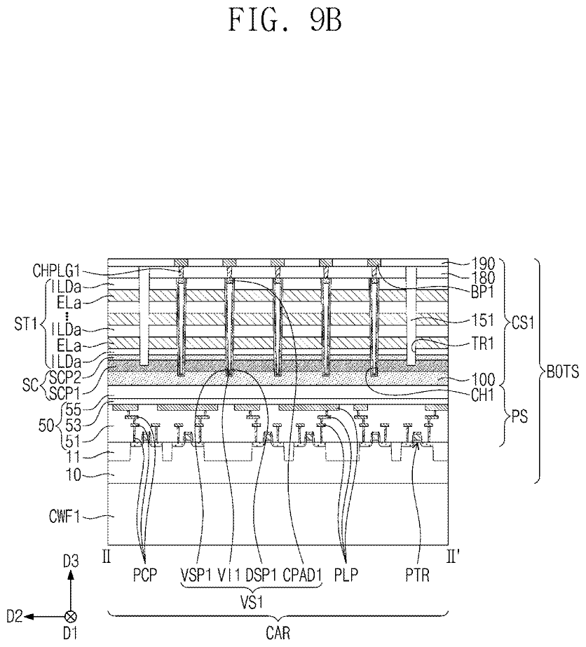

Referring to FIGS. 9A and 9B, the first channel plugs CHPLG1, the first cell contact plugs CPLG1, the source contact plug SPLG, and the peripheral penetration plug PPLG may be formed. The formation of the first channel plugs CHPLG1 may include anisotropically etching the first insulating layer 180 using a photomask layer (not shown), depositing a metallic or conductive material thereon, and performing a planarization process on the conductive material to expose the top surface of the first insulating layer 180. The formation of the first cell contact plugs CPLG1, the source contact plug SPLG, and the peripheral penetration plug PPLG may include anisotropically etching the first insulating layer 180 and the first planarization insulating layer 170 using a photomask layer (not shown) formed on the first insulating layer 180, depositing a metallic or conductive material thereon, and performing a planarization process on the conductive material to expose the top surface of the first insulating layer 180. The formation of the first cell contact plugs CPLG1 may further include anisotropically etching one of the first interlayer insulating layers ILDa of the first stack ST1. The formation of the peripheral penetration plug PPLG may further include anisotropically etching the second lower insulating layer 55 and the etch stop layer 53.

The second insulating layer 190 may be formed on the first insulating layer 180. The first to fourth bonding pads BP1, BP2, BP3, and BP4 may be formed in the second insulating layer 190. The formation of the first to fourth bonding pads BP1, BP2, BP3, and BP4 may include forming openings in the second insulating layer 190, forming a conductive layer (not shown) to fill the openings and cover the top surface of the second insulating layer 190, and performing a planarization process on the conductive layer to expose the top surface of the second insulating layer 190. The first bonding pads BP1 may be connected to the first channel plugs CHPLG1, respectively. The second bonding pads BP2 may be connected to the first cell contact plugs CPLG1, respectively. The third bonding pad BP3 may be connected to the source contact plug SPLG. The fourth bonding pad BP4 may be connected to the peripheral penetration plug PPLG. As a result, the bottom structure BOTS may be formed.

Referring to FIGS. 10A and 10B, the metal line layer BML may be formed on a second carrier substrate CWF2, which is different or distinct from the first carrier substrate CWF1. The metal line layer BML may include the interconnection insulating layer BMD, the metal lines BMP, and the interconnection contact plugs BMCP.

The seventh insulating layer 250 may be formed on the interconnection layer BML. The bit lines BL and the first to fourth conductive lines CL1, CL2, CL3, and CL4 may be formed in the seventh insulating layer 250. The bit lines BL and the first to fourth conductive lines CL1, CL2, CL3, and CL4 may extend in the second direction D2.

The sixth insulating layer 240 may be formed on the seventh insulating layer 250. The upper conductive pads CT may be formed in the sixth insulating layer 240. The formation of the upper conductive pads CT may include forming openings in the sixth insulating layer 240, forming an upper conductive pad layer (not shown) to fill the openings and cover the top surface of the sixth insulating layer 240, and performing a planarization process on the upper conductive pad layer to expose the top surface of the sixth insulating layer 240.

A second mold structure MS2 may be formed on the sixth insulating layer 240. The formation of the second mold structure MS2 may include forming a layered structure (not shown), in which the second interlayer insulating layers ILDb and second sacrificial layers SLb are vertically and alternately stacked, and repeatedly performing a patterning process on the layered structure. Thus, the second mold structure MS2 may have a stepwise structure. More specifically, the second mold structure MS2 may have the preliminary pad portions SLp.

In the second mold structure MS2, the second sacrificial layers SLb may be formed of a material which can be etched with a high etch selectivity with respect to the second interlayer insulating layers ILDb. As an example, the second sacrificial layers SLb may be formed of an insulating material different from the second interlayer insulating layers ILDb. For example, the second sacrificial layers SLb may be formed of silicon nitride, and the second interlayer insulating layers ILDb may be formed of silicon oxide.

The second planarization insulating layer 230 may be formed to cover the preliminary pad portions SLp of the second mold structure MS2.

Next, the second vertical channel structures VS2 may be formed to penetrate or extend in the second mold structure MS2. The formation of the second vertical channel structures VS2 may include forming second vertical channel holes CH2 to penetrate or extend in the second mold structure MS2 and sequentially depositing a second data storing layer (not shown) and a second vertical semiconductor layer (not shown) in each of the second vertical channel holes CH2. The second data storing layer may include a second tunneling insulating layer (not shown), a second charge storing layer (not shown), and a second blocking insulating layer (not shown), which are sequentially stacked. The second data storing layer and the second vertical semiconductor layer may be formed by substantially the same method as that for the first data storing layer and the first vertical semiconductor layer. An etch-back process may be performed on the second data storing layer and the second vertical semiconductor layer, which cover bottom surfaces of the second vertical channel holes CH2, to expose top surfaces of the upper conductive pads CT.

The second vertical channel holes CH2 may be filled with a second insulating gapfill layer (not shown). Next, a planarization process may be performed on the second insulating gapfill layer, the second vertical semiconductor layer, and the second data storing layer to expose a top surface of the uppermost one of the second interlayer insulating layers ILDb of the second mold structure MS2. Thereafter, an etch-back process may be performed on an upper portion of the second insulating gapfill layer, a second conductive pad layer (not shown) may be formed to fill the upper portion of the second insulating gapfill layer, and a planarization process may be performed on the second conductive pad layer to expose the top surface of the uppermost one of the second interlayer insulating layers ILDb of the second mold structure MS2. As a result, the second data storage patterns DSP2, the second vertical semiconductor patterns VSP2, the second gapfill insulating patterns VI2, and the second conductive pads CPAD2 may be formed, as previously described with reference to FIGS. 6A and 6B.

Although not shown, the dummy vertical structures DVS may be formed. The dummy vertical structures DVS may be formed by substantially the same method as that for the second vertical channel structures VS2.

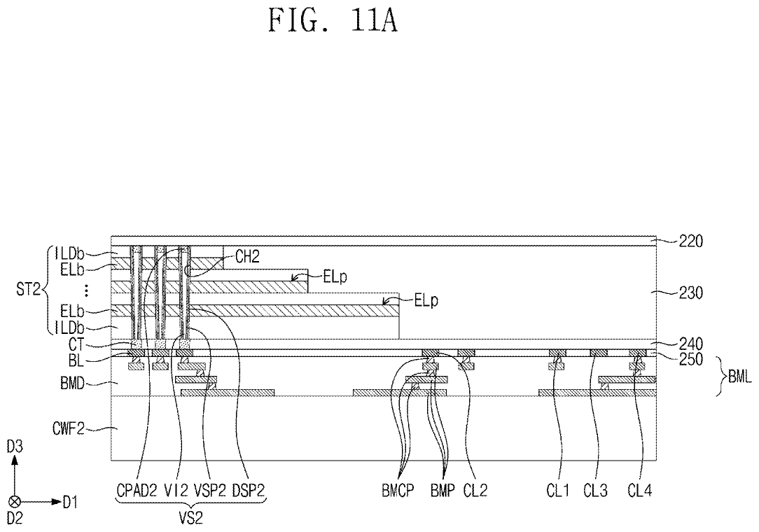

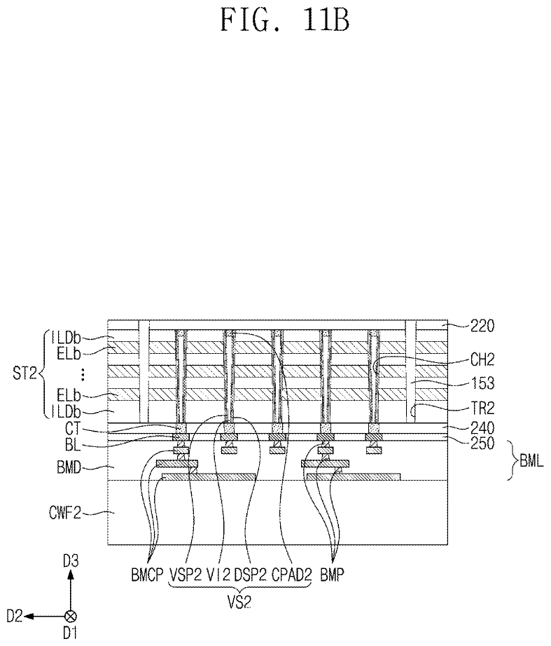

Referring to FIGS. 5, 11A, and 11B, the fifth insulating layer 220 may be formed on the second planarization insulating layer 230 and the second mold structure MS2 to cover the top surfaces of the second vertical channel structures VS2.

The second trenches TR2 may be formed to penetrate or extend in the fifth insulating layer 220, the second planarization insulating layer 230, and the second mold structure MS2. The second trenches TR2 may be formed by the same method as that for the first trenches TR1. Bottom surfaces of the second trenches TR2 may be located at the same level as a bottom surface of the lowermost one of the second interlayer insulating layers ILDb of the second mold structure MS2. The second trenches TR2 may be formed to expose side surfaces of the second interlayer insulating layers ILDb and side surfaces of the second sacrificial layers SLb.

After the formation of the second trenches TR2, the second sacrificial layers SLb, which are exposed through the second trenches TR2, may be selectively removed. The selective removal of the second sacrificial layers SLb may be performed by a wet etching process using etching solution. The second gate electrodes ELb may be formed to fill spaces, which are formed by removing the second sacrificial layers SLb. As a result, the second stack ST2 including the second gate electrodes ELb and the second interlayer insulating layers ILDb may be formed.

The second separation structure 153 may be formed to fill the second trench TR2. The second separation structure 153 may be formed of or include at least one of insulating materials (e.g., silicon oxide, silicon nitride, or silicon oxynitride).

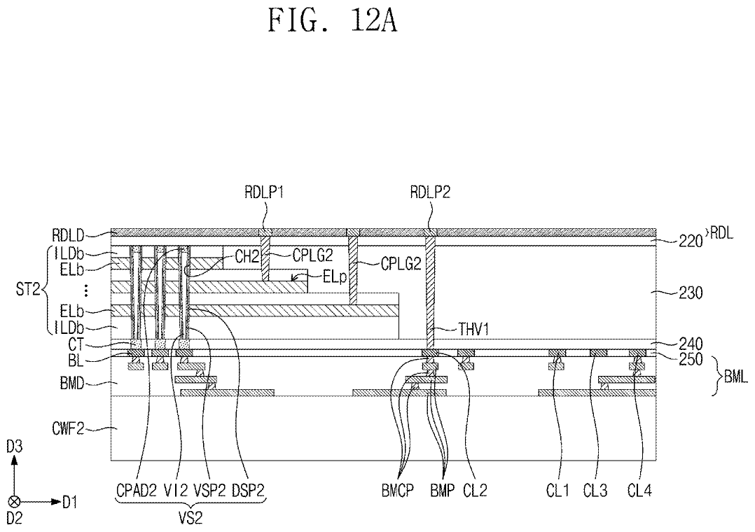

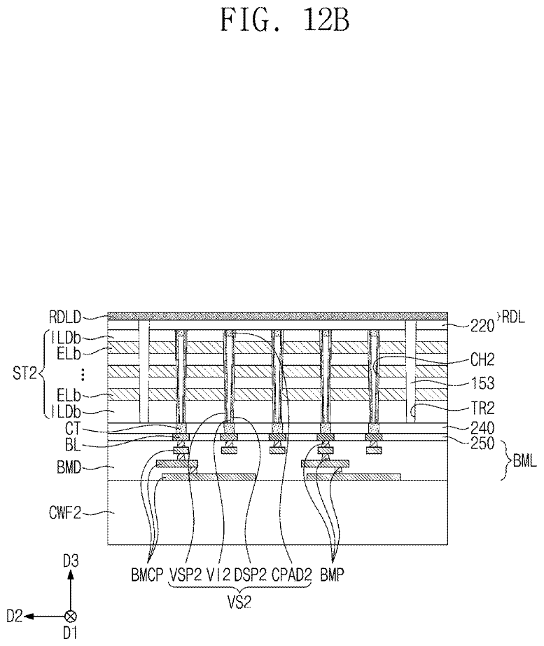

Referring to FIGS. 12A and 12B, the second cell contact plugs CPLG2 and the first penetration electrode THV1 may be formed to penetrate or extend in the fifth insulating layer 220 and the second planarization insulating layer 230. The second cell contact plugs CPLG2 may further penetrate or extend in one of the second interlayer insulating layers ILDb of the second stack ST2 and may be connected to one of the second gate electrodes ELb. The first penetration electrode THV1 may further penetrate or extend in the sixth insulating layer 240 and may be connected to the second conductive line CL2.

The redistribution layer RDL may be formed on the fifth insulating layer 220. The formation of the redistribution layer RDL may include forming the redistribution insulating layer RDLD, performing an anisotropic etching process on the redistribution insulating layer RDLD to form openings exposing top surfaces of the second cell contact plugs CPLG2 and a top surface of the first penetration electrode THV1, forming a redistribution layer (not shown) to fill the openings, and performing a planarization process on the redistribution layer to form the first and second redistribution patterns RDLP1 and RDLP2.

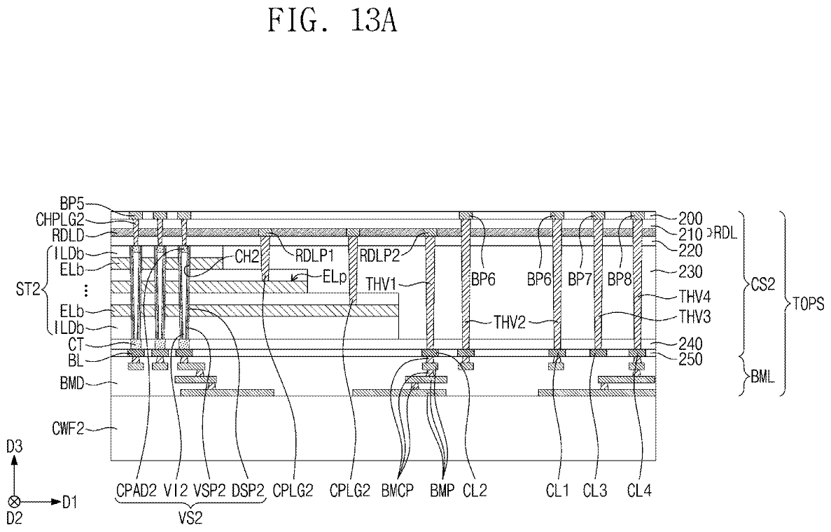

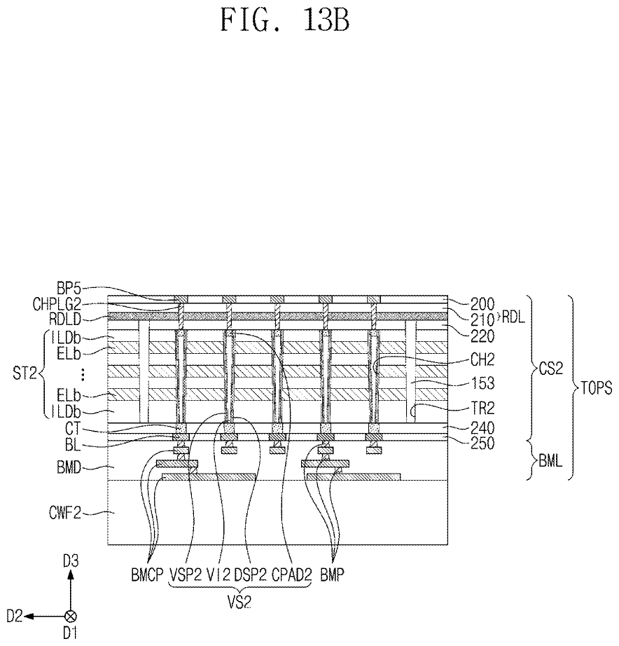

Referring to FIGS. 5, 13A, and 13B, the fourth insulating layer 210 may be formed on the redistribution layer RDL. Next, the second channel plugs CHPLG2 may be formed to penetrate or extend in the fourth insulating layer 210, the redistribution insulating layer RDLD, and the fifth insulating layer 220. The second channel plugs CHPLG2 may be connected to the second vertical channel structures VS2, respectively. The second to fourth penetration electrodes THV2, THV3, and THV4 may be formed to penetrate or extend in the fourth insulating layer 210, the redistribution insulating layer RDLD, the fifth insulating layer 220, the second planarization insulating layer 230, and the sixth insulating layer 240. The second penetration electrodes THV2 may be connected to the first conductive lines CL1. The third penetration electrode THV3 may be connected to the third conductive line CL3. The fourth penetration electrode THV4 may be connected to the fourth conductive line CL4.

The third insulating layer 200 may be formed on the fourth insulating layer 210. The fifth to eighth bonding pads BP5, BP6, BP7, and BP8 may be formed in the third insulating layer 200. In some embodiments, the fifth to eighth bonding pads BP5, BP6, BP7, and BP8 may be formed by substantially the same method as that for the first to fourth bonding pads BP1, BP2, BP3, and BP4. The fifth bonding pads BP5 may be connected to the second channel plugs CHPLG2, respectively. The sixth bonding pads BP6 may be connected to the second penetration electrodes THV2, respectively. The seventh bonding pad BP7 may be connected to the third penetration electrode THV3. The eighth bonding pad BP8 may be connected to the fourth penetration electrode THV4. As a result, the top structure TOPS may be formed.

The fabrication process of the bottom structure BOTS described with reference to FIGS. 7A to 9B may be independently performed in a space that is separated from that for the fabrication process of the top structure TOPS described with reference to FIGS. 10A to 13B. In other words, the bottom and top structures BOTS and TOPS may be simultaneously fabricated in separate spaces, rather than being fabricated at two different times.

Referring to FIGS. 5, 14A, and 14B, the second carrier substrate CWF2 and the top structure TOPS of FIGS. 13A and 13B may be inverted and then may be placed on the bottom structure BOTS of FIGS. 9A and 9B. The second insulating layer 190 of the bottom structure BOTS and the third insulating layer 200 of the top structure TOPS may face each other. The first bonding pads BP1 may vertically overlap with the fifth bonding pads BP5, respectively. The second bonding pads BP2 may vertically overlap with the sixth bonding pads BP6, respectively. The third bonding pad BP3 may vertically overlap with the seventh bonding pad BP7. The fourth bonding pad BP4 may vertically overlap with the eighth bonding pad BP8.

Referring back to FIGS. 5, 6A, and 6B, the first carrier substrate CWF1 and the second carrier substrate CWF2 may be removed. As a result, the three-dimensional semiconductor memory device may be fabricated.

According to some embodiments of the inventive concept, the bottom structure BOTS and the top structure TOPS may be independently fabricated in separate spaces and then may be bonded to each other. Accordingly, it may be possible to reduce a fabrication time, compared to the case of fabricating a three-dimensional semiconductor memory device on one substrate. As a result, it may be possible to reduce a fabrication cost of the three-dimensional semiconductor memory device.

In the conventional method of fabricating a three-dimensional semiconductor memory device, the peripheral circuit structure PS, together with the interconnection layer BML, may be formed on one substrate. Thus, heat, which is generated in a process of forming the interconnection layer BML, may be supplied to the peripheral circuit structure PS, causing a thermal damage issue of the peripheral circuits PTR of the peripheral circuit structure PS, and this may lead to deterioration in electrical and reliability characteristics of the three-dimensional semiconductor memory device. However, according to some embodiments of the inventive concept, since the top structure TOPS is separately manufactured by a process distinct from the bottom structure BOTS, the peripheral circuit structure PS in the bottom structure BOTS may be free from a heat energy supplied in a process of forming the top structure TOPS. That is, it may be possible to reduce the thermal influence on the peripheral circuit structure PS of the bottom structure BOTS in a fabrication process and thereby it may be possible to improve the electrical and reliability characteristics of the three-dimensional semiconductor memory device.

According to some embodiments of the inventive concept, a three-dimensional semiconductor memory device may include a bottom structure and a top structure. The bottom structure and the top structure may be independently fabricated in separate spaces and then may be bonded to each other. Accordingly, it may be possible to reduce a fabrication time, compared to the case of fabricating a three-dimensional semiconductor memory device on one substrate. As a result, it may be possible to reduce a fabrication cost of the three-dimensional semiconductor memory device.

In addition, owing to the separate fabrication of the top and bottom structures, a peripheral circuit structure, which is provided in the bottom structure, may be free from heat energy supplied in a process of fabricating the top structure. That is, it may be possible to reduce the thermal influence on the peripheral circuit structure of the bottom structure in a fabrication process and thereby to improve electrical and reliability characteristics of the three-dimensional semiconductor memory device.

While example embodiments of the inventive concept have been particularly shown and described, it will be understood by one of ordinary skill in the art that variations in form and detail may be made therein without departing from the scope of the attached claims.

What is claimed is:

1. A three-dimensional semiconductor memory device, comprising:
a bottom structure and a top structure on the bottom structure, the bottom structure comprising:
a semiconductor substrate that includes a cell array region and a connection region extending from the cell array region; and
a first stack that includes first gate electrodes and first interlayer insulating layers alternately stacked on the semiconductor substrate,
wherein the top structure comprises a second stack that includes second gate electrodes and second interlayer insulating layers alternately stacked on the first stack,
wherein respective lengths of the first gate electrodes in a second direction decrease as a distance in a first direction from a bottom surface of the semiconductor substrate increases,
wherein respective lengths of the second gate electrodes in the second direction increase as a distance in the first direction from the bottom surface of the semiconductor substrate increases, and
wherein the first direction is perpendicular to the bottom surface of the semiconductor substrate, and the second direction is parallel to the bottom surface of the semiconductor substrate.

2. The semiconductor memory device of claim 1, wherein the bottom structure further comprises a first vertical channel structure that extends in the first stack, and a first bonding pad that is on the first vertical channel structure and is electrically connected to the first vertical channel structure,
wherein the top structure further comprises a second vertical channel structure that extends in the second stack, and a second bonding pad that is on a lower surface of the second vertical channel structure and is electrically connected to the second vertical channel structure, and
wherein the first bonding pad and the second bonding pad are electrically connected to each other.

3. The semiconductor memory device of claim 2, wherein a width of the first vertical channel structure in the second direction increases as a distance in the first direction from the bottom surface of the semiconductor substrate increases, and
wherein a width of the second vertical channel structure in the second direction decreases as a distance in the first direction from the bottom surface of the semiconductor substrate increases.

4. The semiconductor memory device of claim 2, wherein the top structure further comprises a bit line on the second vertical channel structure, and an upper conductive pad between the second vertical channel structure and the bit line, and
wherein the second vertical channel structure is electrically connected to the bit line through the upper conductive pad.

5. The semiconductor memory device of claim 2, further comprising:
a first channel plug between the first vertical channel structure and the first bonding pad, wherein the first vertical channel structure is electrically connected to the first bonding pad through the first channel plug; and
a second channel plug between the second vertical channel structure and the second bonding pad, wherein the second vertical channel structure is electrically connected to the second bonding pad through the second channel plug.

6. The semiconductor memory device of claim 1, wherein the first gate electrodes comprise respective first pad portions on the connection region,
wherein the bottom structure further comprises:
a first cell contact plug that extends in the first direction and is electrically connected to one of the first pad portions; and
a first bonding pad that is on the first cell contact plug and is electrically connected to the first cell contact plug,
wherein the top structure further comprises:
a first penetration electrode that is on the first bonding pad and extends in the first direction; and
a second bonding pad that is between the first bonding pad and the first penetration electrode and is electrically connected to the first penetration electrode, and
wherein the first bonding pad and the second bonding pad are electrically connected to each other.

7. The semiconductor memory device of claim 6, wherein the top structure further comprises an interconnection layer on the first penetration electrode, and a first conductive line between the first penetration electrode and the interconnection layer, and
wherein the first conductive line is electrically connected to the interconnection layer, and the first penetration electrode is electrically connected to the first conductive line.

8. The semiconductor memory device of claim 6, wherein a width of the first cell contact plug in the second direction increases as a distance in the first direction from the bottom surface of the semiconductor substrate increases, and
wherein a width of the first penetration electrode in the second direction decreases as a distance in the first direction from the bottom surface of the semiconductor substrate increases.

9. The semiconductor memory device of claim 6, wherein the second gate electrodes comprise respective second pad portions on the connection region,
wherein the top structure further comprises:
a second cell contact plug electrically connected to one of the second pad portions;
a second penetration electrode that is spaced apart from the second stack in the second direction and extends in the first direction; and
a redistribution layer between the first stack and the second stack, and
wherein the redistribution layer comprises a first redistribution pattern electrically connected to the second cell contact plug, and a second redistribution pattern electrically connected to the second penetration electrode.

10. The semiconductor memory device of claim 9, wherein the top structure further comprises an interconnection layer on the second penetration electrode, and a first conductive line between the second penetration electrode and the interconnection layer,
wherein the second penetration electrode is electrically connected to the first conductive line, and the first conductive line is electrically connected to the interconnection layer, and
wherein the first redistribution pattern and the second redistribution pattern are electrically connected to each other.

11. The semiconductor memory device of claim 9, wherein the redistribution layer is at a level in the first direction that is different from a level of the first bonding pad in the first direction and a level of the second bonding pad in the first direction.

12. A three-dimensional semiconductor memory device, comprising:
a bottom structure and a top structure on the bottom structure, the bottom structure comprising:
a peripheral circuit structure on a semiconductor substrate; and
a first cell array structure on the peripheral circuit structure,
wherein the top structure comprises:
a second cell array structure; and
an interconnection layer on the second cell array structure,
wherein the first cell array structure comprises:
a semiconductor layer;
a first stack that includes first gate electrodes and first interlayer insulating layers alternately stacked on the semiconductor layer;
a cell contact plug electrically connected to one of the first gate electrodes;
a source contact plug that is laterally spaced apart from the first stack and is electrically connected to the semiconductor layer; and
a peripheral penetration plug that is laterally spaced apart from the semiconductor layer and is electrically connected to the peripheral circuit structure,
wherein the second cell array structure comprises:
a second stack that includes second gate electrodes and second interlayer insulating layers alternately stacked on the first cell array structure;
a first penetration electrode that is laterally spaced apart from the second stack and is electrically connected to the cell contact plug;
a second penetration electrode that is laterally spaced apart from the second stack and the first penetration electrode and is electrically connected to the source contact plug; and
a third penetration electrode that is laterally spaced apart from the second stack, the first penetration electrode, and the second penetration electrode and is electrically connected to the peripheral penetration plug, and
wherein the first penetration electrode, the second penetration electrode, and the third penetration electrode are electrically connected to the interconnection layer.

13. The semiconductor memory device of claim 12, wherein respective lengths of the first gate electrodes in a second direction decrease as a distance in a first direction from a bottom surface of the semiconductor substrate increases,
wherein respective lengths of the second gate electrodes in the second direction increase as a distance in the first direction from the bottom surface of the semiconductor substrate increases, and
wherein the first direction is perpendicular to the bottom surface of the semiconductor substrate, and the second direction is parallel to the bottom surface of the semiconductor substrate.

14. The semiconductor memory device of claim 12, wherein the top structure further comprises a redistribution layer between the first stack and the second stack, and
wherein a bottom surface of the redistribution layer is higher than a bottom surface of the first penetration electrode, relative to the bottom surface of the semiconductor substrate.

15. The semiconductor memory device of claim 12, wherein the first cell array structure further comprises a first vertical channel structure that extends in the first stack,
wherein the second cell array structure further comprises a second vertical channel structure that extends in the second stack,
wherein the bottom structure further comprises a first bonding pad between the first vertical channel structure and the second cell array structure,
wherein the top structure further comprises a second bonding pad between the second vertical channel structure and the first bonding pad,
wherein the first vertical channel structure is electrically connected to the first bonding pad, and the second vertical channel structure is electrically connected to the second bonding pad, and
wherein the first bonding pad and the second bonding pad are in contact with each other.

16. A method of fabricating a three-dimensional semiconductor memory device, comprising:
forming a bottom structure on a first carrier substrate;
forming a top structure on a second carrier substrate distinct from the first carrier substrate;
inverting the second carrier substrate and the top structure and placing them on the bottom structure;
bonding the top structure to the bottom structure; and
removing the first carrier substrate and the second carrier substrate,
wherein the forming of the bottom structure comprises:
forming a peripheral circuit structure on the first carrier substrate; and
forming a first cell array structure on the peripheral circuit structure,
wherein the forming of the top structure comprises:
forming an interconnection layer on the second carrier substrate; and
forming a second cell array structure on the interconnection layer, and
wherein the forming of the second cell array structure comprises forming a redistribution layer.

17. The method of claim 16, wherein the forming of the first cell array structure comprises:
forming a first stack on the peripheral circuit structure;
forming a first vertical channel structure extending in the first stack; and
forming a first bonding pad that is on the first vertical channel structure and is electrically connected to the first vertical channel structure,
wherein the forming of the second cell array structure comprises:
forming a second stack on the interconnection layer;
forming a second vertical channel structure extending in the second stack; and
forming a second bonding pad that is on the second vertical channel structure and is electrically connected to the second vertical channel structure, and
wherein the bonding of the top structure to the bottom structure comprises bringing the first bonding pad into contact with the second bonding pad.

18. The method of claim 17, wherein the forming of the second stack comprises forming gate electrodes and interlayer insulating layers alternately stacked on the interconnection layer, and
wherein the forming of the second cell array structure further comprises:
forming a cell contact plug that is electrically connected to one of the gate electrodes; and
forming a penetration electrode that is spaced apart from the second stack and is electrically connected to the interconnection layer.

19. The method of claim 18, wherein the forming of the redistribution layer comprises:
forming a first redistribution pattern electrically connected to the cell contact plug; and
forming a second redistribution pattern electrically connected to the penetration electrode, and
wherein the first redistribution pattern and the second redistribution pattern are electrically connected to each other.

20. The method of claim 16, wherein the forming of the second cell array structure further comprises:
forming a bit line on the interconnection layer; and
forming an upper conductive pad on the bit line.
